(19) United States
(12) Patent Application Publication
(10) Pub. No.: US 2006/0014384 A1
(43) Pub. Date: Jan. 19, 2006

(54) Method of forming a layer and forming a capacitor of a semiconductor device having the same layer

(76) Inventors: Jong-Cheol Lee, Seoul (KR); Ki-Vin Im, Suwon-si (KR); Sung-Tae Kim, Seoul (KR); Young-Sun Kim, Suwon-si (KR); Cha-Young Yoo, Suwon-si (KR); Han-Mei Choi, Seoul (KR); Gab-Jin Nam, Seoul (KR); Seung-Hwan Lee, Seoul (KR)

Correspondence Address: F. CHAU & ASSOCIATES, LLC, 130 WOODBURY ROAD, WOODBURY, NY, 11797, US

(21) Appl. No.: 11/140,552

(22) Filed: May 27, 2005

Related U.S. Application Data
(63) Continuation-in-part of application No. 10/403,572, filed on Mar. 31, 2003, now Pat. No. 6,933,245.

(30) Foreign Application Priority Data
May 28, 2004 (KR) 2004-38058
Jun. 5, 2002 (KR) 2002-31724

(51) Int. Cl. H01L 21/20; H01L 21/44

(52) U.S. Cl. 438/680; 438/381

(57) ABSTRACT

In a method of forming a layer using an atomic layer deposition process, after a substrate is loaded into a chamber, a first reactant is provided onto the substrate. The first reactant is partially chemisorbed on the substrate. A second reactant is introduced into the chamber to form a preliminary layer on the substrate by chemically reacting the second reactant with the chemisorbed first reactant. Impurities in the preliminary layer and unreacted reactants are simultaneously removed using a plasma for removing impurities to thereby form the layer on the substrate. The impurities in the layer may be effectively removed so that the layer may have reduced leakage current.

### CROSS-REFERENCE TO RELATED APPLICATIONS

This application claims priority under 35 USC § 119 to Korean Patent Application No. 2004-38058 filed on May 28, 2004, the content of which is incorporated herein by reference in its entirety. In addition, this application is a continuation-in-part application of and claims priority under 35 U.S.C. § 120 of co-pending U.S. patent application Ser. No. 10/403,572 filed on Mar. 31, 2003 and entitled “METHOD OF FORMING A THIN FILM WITH A LOW HYDROGEN CONTENT”, which claims priority under 35 U.S.C. § 119 from Korean Patent Application No. 2002-31724 filed on Jun. 5, 2002, both of which are incorporated herein by the reference in their entirety.

### BACKGROUND OF THE INVENTION

1. Field of the Invention

Exemplary embodiments of the present invention relate to methods of forming a layer and methods of forming a semiconductor capacitor having the layer. More particularly, exemplary embodiments of the present invention relate to methods of forming a semiconductor device layer using an atomic layer deposition (ALD) process and methods of forming a semiconductor capacitor including the layer.

2. Description of the Related Art

As semiconductor devices become more highly integrated, the processing conditions for forming a semiconductor device layer, such as having a low heat budget, good step coverage, precise control of a thickness of the layer, and low contaminated environment, etc., have become more strictly controlled.

Conventional chemical vapor deposition (CVD) processes, such as a low pressure chemical vapor deposition (LPCVD) process and a plasma enhanced chemical vapor deposition (PECVD) process may not be suitable for forming a layer of a highly integrated semiconductor device. For example, a layer is formed at a relatively high temperature in the conventional CVD process may severely deteriorate the characteristics of a semiconductor device due to the high heat budget and the redistribution of dopants. In addition, the layer formed by the conventional CVD process may have an uneven thickness because of underlying structures formed on the substrate, thereby causing a loading effect on the semiconductor device. That is, a portion of the layer positioned on some densely arranged underlying structures has a thickness substantially thinner than that of other portions of the layer formed on other sparsely arranged underlying structures because of the loading effects of the semiconductor device.

A layer formed by a conventional LPCVD process may have a high impurity content, such as hydrogen, and may also have poor step coverage. In the meantime, when a conventional PECVD process is used to form a layer of a semiconductor device, the layer may have poor step coverage even though the layer may have been formed at a relatively low temperature in comparison with the layer formed through the conventional LPCVD process.

Considering the above-mentioned problems, an atomic layer deposition (ALD) process has been developed because a layer of a semiconductor device having good step coverage may be formed at a relatively low temperature without having any loading effects.

For example, U.S. Pat. No. 6,124,158 (issued to Dautartas. et al.) discloses a method of forming a thin layer employing an ALD process. A reactant is first introduced onto a substrate in a chamber to form a monolayer on the substrate. Then, a second reactant is introduced onto the monolayer to form a desired thin layer on the substrate by reacting the second reactant with the monolayer. The chamber is purged using an inert gas before and after introducing the second reactant, thereby preventing the reaction of the first reactant and/or the second reactant except on the surface of the substrate.

A silicon nitride (SiN) layer may be formed through an ALD process by reducing the temperature by about 100° C. from a temperature of about 780° C. in the conventional LPCVD process. Thus, the silicon nitride layer may have improved conformality on a substrate. Generally, the silicon nitride layer may be used as a capping layer for protecting underlying layers because the silicon nitride layer has good diffusion barrier characteristics. In addition, the silicon nitride layer may be frequently used as an etching stop layer in an etching process because the silicon nitride layer has high etching selectivity relative to an oxide layer.

Even though a layer is formed using the ALD process, however, the layer may be contaminated by impurities within the layer. Namely, the impurities such as carbon and/or hydrogen contained in the layer may cause a failure of the semiconductor device because the leakage current from the layer may increase. Further, the failures of the semiconductor device due to the impurities may be serious as the semiconductor device becomes more highly integrated.

While the silicon nitride layer formed using the ALD process may have good step coverage and may be formed at a low temperature, characteristics of the silicon nitride layer may deteriorate in a dry etching process and/or a wet etching process because the silicon nitride layer formed by the ALD process may have a higher hydrogen concentration than that of the silicon nitride layer that is formed during the high temperature CVD process. When the silicon nitride layer having a high hydrogen concentration is used as a spacer is formed on the sidewall of a gate electrode of a transistor, hydrogen atoms in the silicon layer may diffuse into a gate oxide layer. This may occur because the heat budget generated in subsequent processes results in the diffused hydrogen atoms serving as an impurity trap, which may deteriorate the characteristics of the transistor.

FIG. 1 is a graph illustrating hydrogen contents in silicon nitride layers formed using various deposition processes. In FIG. 1, the hydrogen contents in the silicon nitride layers are measured using an FTIR-RAS (Fourier Transform Infrared Reflection Absorption Spectroscopy). In FIG. 1, T350, T400, T450, T500, T550 and T595 indicate silicon nitride layers formed by ALD processes at a temperature of about 350° C., about 400° C., about 450° C., about 500° C., about 550° C. and about 595° C., respectively. In addition, LP680 and LP780 represent silicon nitride layers formed by LPCVD processes at a temperature of about 680° C. and about 780° C., respectively. Moreover, PE-CVD indicates a silicon nitride layer formed by a PECVD process.

As illustrated in FIG. 1, the hydrogen contents in the silicon nitride layers formed by the ALD processes are higher than that of the silicon nitride layer formed by the LPCVD process at a high temperature of 780° C. As the design criteria for fabricating a semiconductor device is reduced, the low temperature manufacturing process in the fabrication of the semiconductor devices becomes more important. Thus, the ALD process is more widely employed in the fabrication of semiconductor devices. In the ALD process for forming a semiconductor device layer, the impurity content, such as hydrogen, should be minimized to ensure proper electrical characteristics of the layer.

For example, U.S. Pat. No. 5,876,918 discloses a method of forming an insulation layer such as a nitride layer by a CVD process using a gas that does not contain a chemical bond of nitride and hydrogen (N—H bond), e.g., nitrogen (N₂) gas. However, the insulation layer may have an uneven thickness as well as poor quality.

In addition, the art also discloses a method of forming a nitride layer having a low hydrogen content using a nitrogen plasma or a nitrogen radical. However, when the nitride layer is formed on a substrate using plasma or radical that is directly provided onto the substrate, the interface state density of a semiconductor device may be increased and fixed charges in the nitride layer may also be augmented.

Besides hydrogen, carbon is also one of the conventional impurities generated in the fabrication of a semiconductor device using an organic precursor. Particularly, the organic precursor having a gas phase is deposited on a substrate using an ALD process to form a layer on the substrate. Here, carbon previously contained in the organic precursor may remain in the layer, which may cause failure of the semiconductor device.

In order to solve the above-mentioned problems, a method of treating a layer at a high temperature has been developed. According to this method, after forming the layer, such as a dielectric layer, on a substrate by placing it in a chamber, the layer is treated at a high temperature so as to change the carbon in the layer into a volatile compound such as carbon monoxide and/or carbon dioxide. Then, the volatile compound is removed from the chamber so that impurities, such as carbon, are removed from the layer. However, such a method may not be employed for forming a layer at a substantially low temperature. In addition, the contamination on the layer due to carbon may become more serious at high temperatures because the organic precursor may thermally decompose.

Further, a method of treating a layer with plasma has been developed in order to reduce the contamination of the layer. However, high energy applied to the substrate may cause damage to the layer in the plasma treatment, and also the size and the thickness of the layer may be reduced. Moreover, an additional process for treating the layer is carried out to increase the manufacturing cost of the semiconductor device.

According to the above U.S. Pat. No. 6,124,158, after introducing reactants into the chamber to form the layer on the substrate, ozone (O₃) is introduced into the chamber to remove impurities from the layer during the purging process. However, this process may only be employed for removing impurities in an oxide layer.

### SUMMARY OF THE INVENTION

In one embodiment, the present invention provides a method of forming a layer having a low hydrogen content at a low temperature.

In another embodiment, the present invention provides a method of forming a layer having a low impurity content by employing an atomic layer deposition process.

In yet another embodiment, the present invention provides a method of forming a capacitor including a dielectric layer that has excellent electrical characteristics.

In accordance with one aspect of the present invention, there is provided a method of forming a layer. In the method, after forming a layer on a substrate, a nitrogen (N₂) remote plasma treatment is carried out on the layer to reduce the content of hydrogen of the layer.

According to another exemplary embodiment of the present invention, a substrate is loaded into a chamber. A reactant is introduced into the chamber, thereby chemisorbing the reactant to the substrate. The substrate is then treated using nitrogen (N₂) remote plasma to remove hydrogen from the chemisorbed reactant.

According to another exemplary embodiment of the present invention, after loading a substrate into a chamber, a first reactant is introduced into the chamber. The first reactant is chemisorbed to the substrate to form an adsorption layer on the substrate. The adsorption layer is then treated with nitrogen (N₂) remote plasma to remove hydrogen from the adsorption layer. Then, a second reactant is introduced into the chamber to form a layer on the substrate.

According to an exemplary embodiment of the present invention, a substrate is loaded in the chamber. A first reactant is chemisorbed to the substrate by introducing the first reactant into the chamber, thereby forming an adsorption layer on the substrate. A non-chemisorbed first reactant is removed from the chamber. A second reactant is reacted with the adsorption layer by providing the second reactant onto the adsorption layer so that a layer is formed on the substrate. Then, a nitrogen (N₂) remote plasma treatment is performed on the layer to reduce the hydrogen content of the layer.

In accordance with another aspect of the present invention, there is provided a method of forming a layer. In the method, a layer is formed on a substrate using an atomic layer deposition process. Impurities are removed from the layer using plasma for removing the impurities.

According to another exemplary embodiment of the present invention, a substrate is loaded into a chamber. By introducing a first reactant into the chamber, the first reactant is chemisorbed to the substrate. A second reactant is introduced into the chamber. Here, the second reactant is chemically reacted with the chemisorbed first reactant to thereby form a layer on the substrate. Impurities are removed from the layer using plasma for removing the impurities.

In exemplary embodiments of the present invention, the plasma for removing the impurities may be generated adjacent to the substrate. Particularly, a gas for removing the impurities is introduced into the chamber, and then the gas is excited to the plasma phase so as to form the plasma for removing the impurities.

In exemplary embodiments of the present invention, the plasma may be generated apart from the substrate. In particular, the plasma for removing the impurities is formed on the outside of the chamber, and then is introduced into the chamber.

In order to reduce damages to the layer, an additional second reactant may be introduced into the chamber. Here, a non-chemisorbed additional second reactant may be removed from the chamber.

In accordance with still another aspect of the present invention, there is provided a method of forming a capacitor of a semiconductor device. In the method, a substrate including a lower electrode is loaded into a chamber. A first reactant is provided onto the substrate to form an absorption layer on the lower electrode. A remaining first reactant is then removed from the chamber. A second reactant is provided onto the absorption layer to form a dielectric layer on the lower electrode. Impurities contained in the dielectric layer are removed using plasma for removing the impurities. An upper electrode is then formed on the dielectric layer.

According to an embodiment of the present invention, an adsorption layer formed using a first reactant or a layer formed by reacting reactants in the adsorption layer with a second reactant may be treated with nitrogen (N₂) plasma. Therefore, hydrogen bonds of the adsorption layer or the layer may be removed. Thus, the layer may have low hydrogen content. In addition, the plasma for removing impurities is applied to a layer formed by an ALD process. Therefore, the impurities in the layer may be effectively removed to reduce leakage current from the layer and to form the layer having excellent insulation property. Furthermore, when the layer is employed for a dielectric layer of a capacitor, the capacitor may have improved electrical characteristics and enhanced reliability.

### BRIEF DESCRIPTION OF THE DRAWINGS

Exemplary embodiments of the present invention will become readily apparent along with the following detailed description when considered in conjunction with the accompanying drawings wherein:

FIG. 1 is a graph illustrating hydrogen contents of silicon nitride layers formed by various deposition processes in accordance with an embodiment of the present invention;

FIG. 2 is a cross sectional view illustrating an apparatus for forming a layer using an atomic layer deposition process in accordance with an exemplary embodiment of the present invention;

FIGS. 3A to 3D are cross sectional views illustrating a method of forming a layer using the apparatus in FIG. 2 in accordance with an embodiment of the present invention;

FIG. 4 is a cross sectional view illustrating an apparatus for forming a layer using an atomic layer deposition process in accordance with an exemplary embodiment of the present invention;

FIGS. 5A to 5F are cross sectional views illustrating a method of forming a layer using the apparatus in FIG. 4 in accordance with an exemplary embodiment of the present invention;

FIGS. 6A to 6F are cross sectional views illustrating a method of forming a layer using the apparatus in FIG. 2 in accordance with an exemplary embodiment of the present invention;

FIGS. 7A to 7E are cross sectional views illustrating a method of forming a capacitor in accordance with an exemplary embodiment of the present invention;

FIG. 8 is a flow chart illustrating a method of forming a layer in accordance with an exemplary embodiment of the present invention;

FIG. 9 is a flow chart illustrating a method of forming a layer in accordance with an exemplary embodiment of the present invention;

FIG. 10 is a flow chart illustrating a method of forming a layer in accordance with an exemplary embodiment of the present invention;

FIG. 11 is a flow chart illustrating a method of forming a layer in accordance with an exemplary embodiment of the present invention;

FIG. 12 is a flow chart illustrating a method of forming a layer in accordance with an exemplary embodiment of the present invention;

FIG. 13 is a flow chart illustrating a method of forming a layer in accordance with an exemplary embodiment of the present invention;

FIG. 14 is a flow chart illustrating a method of forming a layer in accordance with an exemplary embodiment of the present invention;

FIG. 15 is a flow chart illustrating a method of forming a layer in accordance with an exemplary embodiment of the present invention;

FIG. 16 illustrates hydrogen contents of silicon nitride layers in accordance with the present invention;

FIG. 17 is a graph illustrating carbon contents of hafnium oxide layers obtained using an X-ray photoemission spectroscopy method in accordance with an embodiment of the present invention;

FIG. 18 is a graph illustrating oxygen contents of hafnium oxide layers obtained using an X-ray photoemission spectroscopy method in accordance with an embodiment of the present invention; and

FIG. 19 is a graph illustrating hafnium contents of hafnium oxide layers obtained using an X-ray photoemission spectroscopy method in accordance with an embodiment of the present invention.

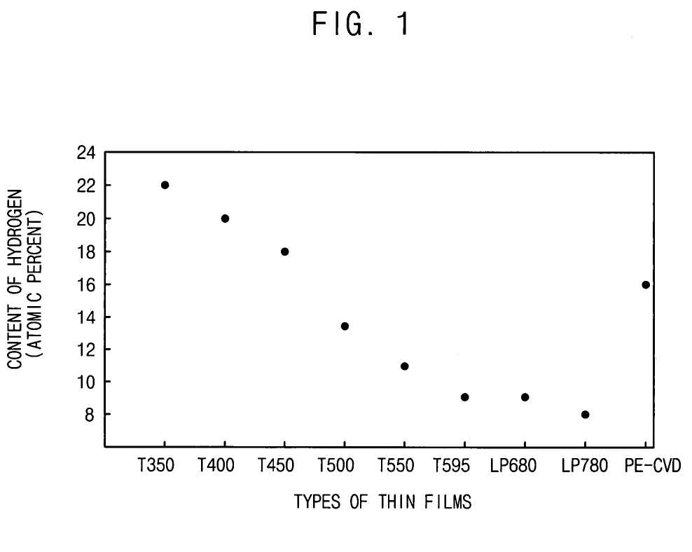

### DESCRIPTION OF THE PREFERRED EMBODIMENTS

Exemplary embodiments of the present invention now will be described more fully hereinafter with reference to the accompanying drawings, in which example embodiments of the invention are shown. Exemplary embodiments of the present invention may, however, be embodied in many different forms and should not be construed as limited to the example embodiments set forth herein; rather, these embodiments are provided so that this disclosure will be thorough and complete, and will fully convey the scope of the invention to those skilled in the art. In the drawings, the thickness of layers and regions are exaggerated for clarity. Like reference numerals refer to similar or identical elements throughout. It will be understood that when an element such as a layer, region or substrate is referred to as being “on” or “onto” another element, it can be directed onto the other element or intervening elements.

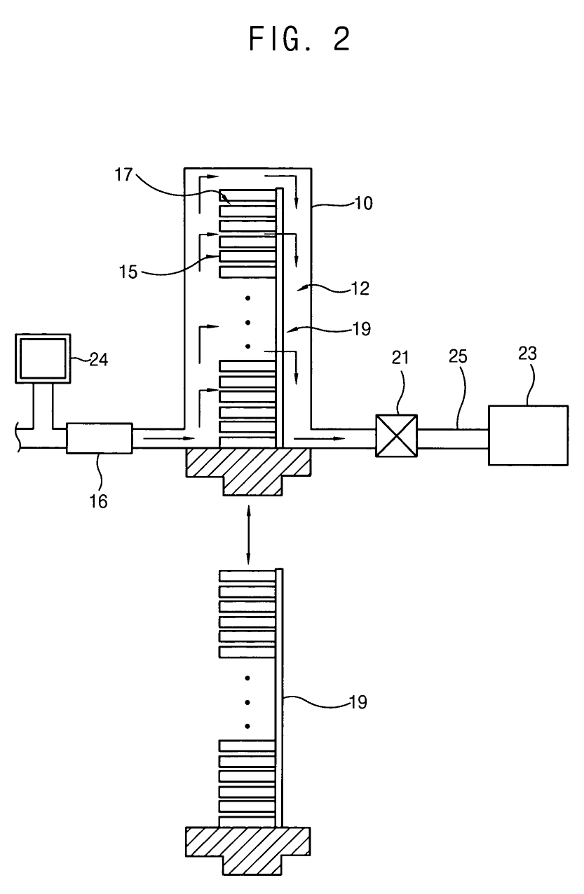

FIG. 2 is a cross sectional view illustrating an apparatus for forming a layer by employing an atomic layer deposition process in accordance with an exemplary embodiment of the present invention.

Referring to FIG. 2, the apparatus includes a chamber 10, a pump 23, a remote plasma generator 24 and a boat 19.

The chamber 10 has a unitary reaction space 12 where a layer is formed on a substrate 15. An element such as a heater installed on a side of the chamber 10 may be omitted for simplicity. The chamber 10 may be a vertical type chamber, which is substantially similar to a conventional LPCVD furnace disclosed in U.S. Pat. Nos. 5,217,340 and 5,112,641. However, other type of chamber, e.g., a horizontal type chamber, may be used for forming the layer in accordance with the present invention.

A plurality of substrates 15 or wafers is placed in the reaction space 12 provided in the chamber 10. A series of processes for forming the layer may be sequentially carried out in the space 12.

A boat 19 including the substrates 15 therein is provided under the chamber 10. For example, about twenty to about fifty substrates 15 are loaded in the boat 19. The boat 19 having the substrates 15 is loaded into the chamber 10 and unloaded from the chamber 10 by a transferring member (not shown). For example, the boat 19 is loaded upwardly into the chamber 10 and unloaded downwardly from the chamber 10.

A reactant for forming the layer and plasma for treating the layer are introduced into the chamber 10 through an introducing member 16 connected to one side on the chamber 10. A remote plasma generator 24 is connected to the introducing member 16, and also a gas source (not shown) is connected to the introducing member 16.

A pump 23 for ventilating the chamber 10 is connected to the other side of the chamber 10 through an exhaust pipe 25. A pressure control valve 21 is installed between the pump 23 and the chamber 10.

When the processes for forming the layer are performed in the chamber 10, a bundle 14 of the substrates 15 is loaded into the unitary reaction space 12 of the chamber 10 by the boat 19. For example, about twenty to about fifty substrates 15 may comprise the bundle 14 of the substrates 15. That is, about twenty to about fifty substrates 15 may be simultaneously processed through an ALD process to form the layers on the substrates 15, respectively. Here, the layers are formed on surfaces 17 of the substrates 15.

The bundle 14 of the substrates 15 is arranged and loaded in the boat 19. The boat 19 typically includes quartz or other materials, and has a plurality of grooves on an inside thereof. The substrates 15 are respectively positioned in the grooves of the boat 19. Since the boat 19, including the bundle 14 of the substrates 15, is loaded into the chamber 10, the bundle 14 of the substrates 15 is simultaneously loaded into the unitary reaction space 12 of the chamber 10.

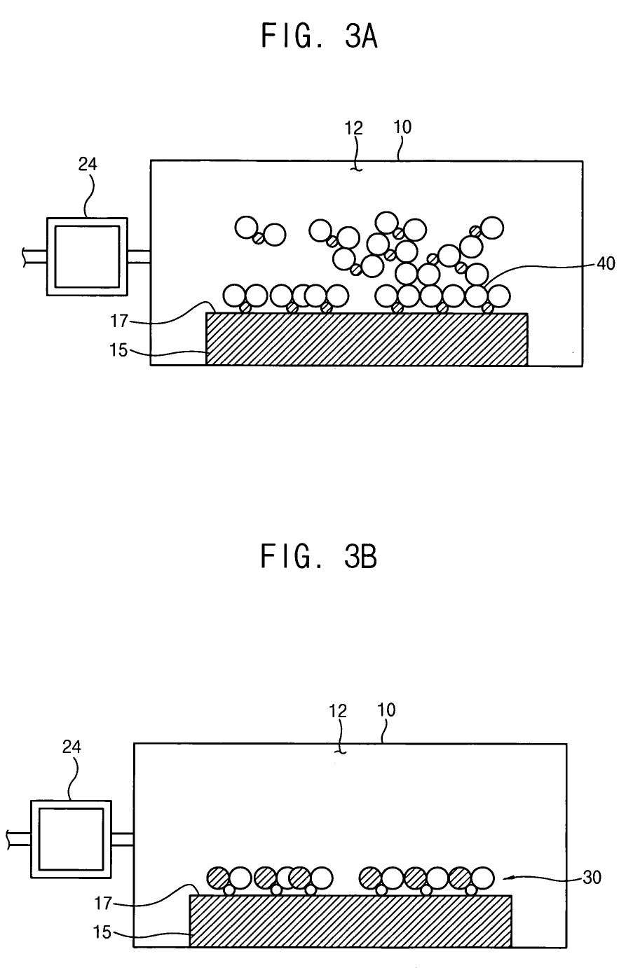

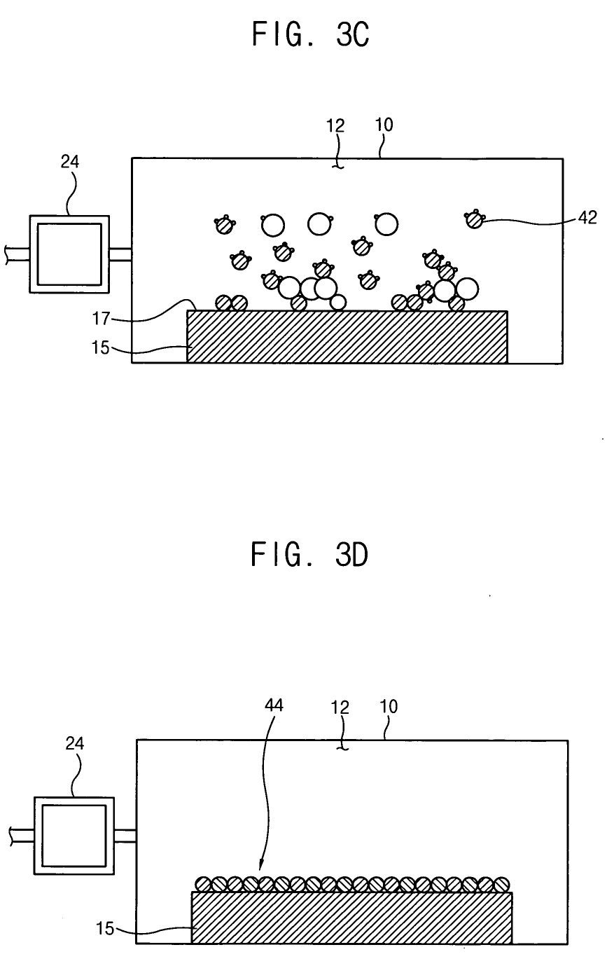

FIGS. 3A to 3D are cross sectional views illustrating a method of forming a layer using the apparatus in FIG. 2. In FIGS. 3A to 3D, the introducing member 16 will be omitted for simplicity.

Referring to FIGS. 2 and 3A, after the substrates 15 are loaded into the chamber 10 by the boat 19, a first reactant 40 or a first gas including the first reactant 40 such as dichlorosilane (DCS, SiH₂Cl₂) gas is introduced into the unitary reaction space 12 of the chamber 10. The first reactant 40 is provided into the unitary reaction space 12 of the chamber 10 through the introducing member 16.

The first reactant 40 is partially chemisorbed (chemically absorbed) onto the surface 17 of the substrate 15 placed in the unitary reaction space 12, thereby forming an adsorption layer 30 on the surface 17 of the substrate 15.

Referring to FIGS. 2 and 3B, a first purge gas is introduced into the chamber 10 to remove a non-chemisorbed first reactant 40 from the adsorption layer 30. The non-chemisorbed first reactant 40 may correspond to a physisorbed (physically absorbed) first reactant 40 to the surface 17 of the substrate 15 and/or drifting first reactant 40 in the chamber 10. The first purge gas may include an inactive gas, for example, a nitrogen gas.

The first purge gas and the non-chemisorbed first reactant 40 are exhausted from the chamber 10 by the pump 23 through the exhaust pipe 25 and a pressure control valve 21. When the first purge gas is introduced into the chamber 10 through the introducing member 16, the pressure control valve 21 is dosed. When all or substantially all of the non-chemisorbed first reactant 40 is removed from the chamber 10, the pressure control valve 21 is opened. Thus, the non-chemisorbed first reactant 40 is removed from the chamber 10 through the exhaust pipe 25 by pumping out the non-chemisorbed first reactant 40 using the pump 23.

Referring to FIGS. 2 and 3C, after the non-chemisorbed first reactant 40 is removed from the unitary reaction space 12, a second reactant 42 or a gas including the second reactant, e.g., an ammonia (NH₃) gas is introduced into the unitary reaction space 12 of the chamber 10.

The second reactant 42 is chemically reacted with the adsorption layer 30 formed on the substrate 10.

Referring to FIGS. 2 and 3D, after the second reactant 42 is chemically reacted with the adsorption layer 30, a layer 44 is formed on the substrate 15. For example, the layer 44 includes silicon nitride.

A second purge gas is introduced into the chamber 10 to remove all or substantially all of non-chemically reacted second reactant 42 from the reaction space 12 of the chamber 10 as described above. The second purge gas may include an inactive gas, for example, a nitrogen gas.

The layer 44 having a desired thickness may be formed on the substrate 15 by repeatedly performing the steps of introducing the first reactant 40, the first purge gas, the second reactant 42 and the second purge gas.

In an exemplary embodiment of the present invention, after the adsorption layer 30 is formed on the surface 17 of the substrate 15 by chemisorbing the first reactant 40 to the substrate 15, the hydrogen content of the adsorption layer 30 may be reduced by treating the adsorption layer 30 with a nitrogen (N₂) remote plasma. The remote nitrogen plasma is provided from the remote plasma generator 24 into the reaction space 12 of the chamber 10.

In an exemplary embodiment of the present invention, the first nitrogen remote plasma treatment may be carried out with respect to the adsorption layer 30 without additionally purging for removing all or substantially all of the non-chemisorbed first reactant 40 using the first purge gas. Here, the non-chemisorbed first reactant 40 may be removed from the chamber 10 by the nitrogen remote plasma for reducing the hydrogen content of the adsorption layer 30.

In an exemplary embodiment of the present invention, the first nitrogen remote plasma treatment may be carried out on the adsorption layer 30 after venting the chamber 10 using the first purge gas.

When the first nitrogen remote plasma treatment is performed on the adsorption layer 30 after the adsorption layer 30 is formed on the surface 17 of the substrate 15, activated nitrogen (N₂) molecules collide with the surface 17 of the substrate 15 so that hydrogen bonds in the adsorption layer 30, such as chemical bonds between silicon atoms and hydrogen atoms (Si—H bond), may be removed from the adsorption layer 30. Then, the second reactant 42 is introduced into the chamber 10 to thereby form the layer 44 having a greatly reduced hydrogen content on the substrate 15.

In an exemplary embodiment of the present invention, the nitrogen plasma gas may be generated at an outside of the chamber 10, and then introduced into the chamber 10. Hence, the damage to the substrate 15 may be prevented while forming the layer 44 on the substrate 15.

In an exemplary embodiment of the present invention, after the second reactant 42 is chemically reacted with reactants in the adsorption layer 30 to form the layer 44 on the substrate 15, a second nitrogen remote plasma treatment is also performed concerning the layer 44 to reduce the hydrogen content of the layer 44.

In an exemplary embodiment of the present invention, the second nitrogen remote plasma treatment may be performed against the layer 44 without additionally venting the chamber 10 using the second purge gas for removing the non-chemically reacted second reactant 42 In an exemplary embodiment of the present invention, the second nitrogen remote plasma treatment may be carried out on the layer 44 after the chamber 10 is vented using the second purge gas.

When the nitrogen remote plasma treatment is performed on the layer 44 after the layer 44 is formed on the substrate 15 by introducing the second reactant 42 onto the adsorption layer 30 formed on the substrate 15, hydrogen bonds in the layer 44, such as nitrogen-hydrogen bonds (N—H bond), are broken in the second nitrogen remote plasma treatment. Therefore, the hydrogen content on the layer 44 may be drastically reduced.

In an exemplary embodiment of the present invention, the first nitrogen remote plasma treatment is performed on the adsorption layer 30, and the second nitrogen remote plasma treatment is carried out on the layer 44. The non-chemisorbed first reactant 40 may be removed from the chamber 10 in the first nitrogen remote plasma treatment. Alternatively, the non-chemisorbed first reactant 40 may be removed from the chamber 10 using the first purge gas before the first nitrogen remote plasma treatment. In addition, the non-chemically reacted second reactant 42 may be removed from the chamber 10 in the second nitrogen remote plasma treatment or using the second purge gas before the second nitrogen remote plasma treatment.

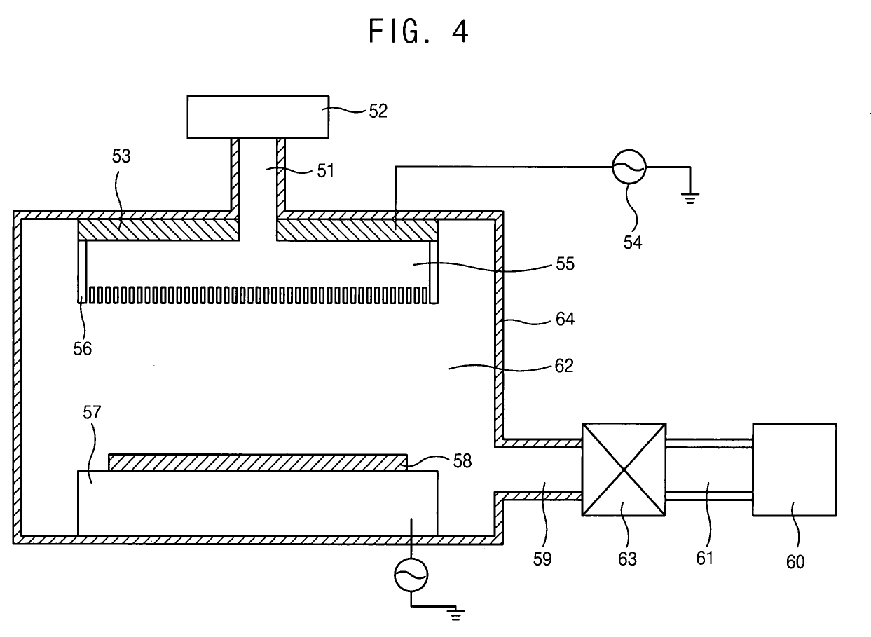

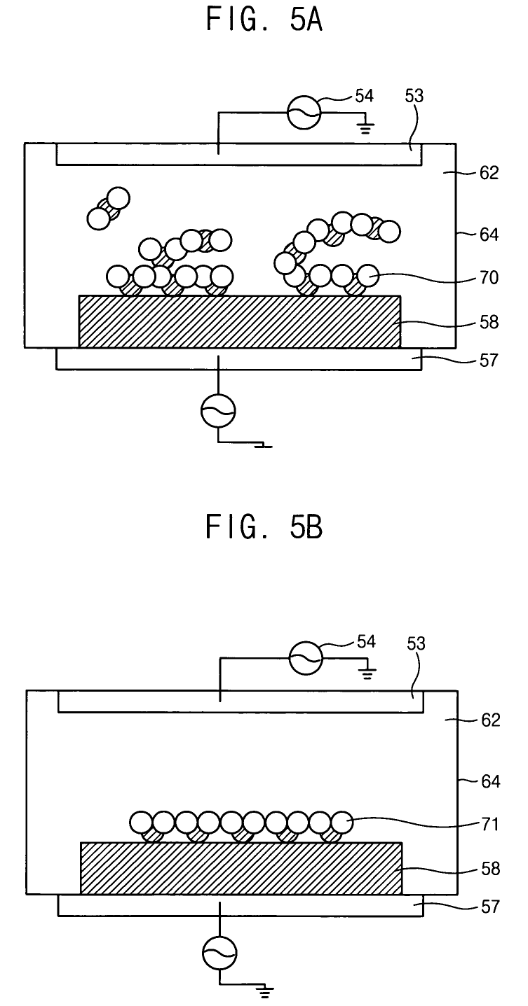

FIG. 4 is a cross sectional view illustrating an apparatus for forming a layer using an atomic layer deposition (ALD) process in accordance an exemplary embodiment of the present invention.

Referring to FIG. 4, the apparatus for forming the layer includes a chamber 64 having a reaction spacer 62 provided therein.

A gas inlet 51 is connected to an upper portion of the chamber 64, and a gas supply member 52 is connected to the gas inlet 51. The gas supply member 52 provides a first reactant, a second reactant and purge gases into the reaction spacer 62.

An electrode 53 is installed beneath an inner upper face of the chamber 64, and a radio frequency (RF) power source 54 is electrically connected to the electrode 53. The RF power source 54 applies a radio frequency (RF) power to the electrode 53 so that the electrode 53 excites a gas to form plasma in a buffer spacer 55.

A showerhead 56 is installed under the electrode 53 to uniformly provide the plasma onto a substrate 58 positioned on a chuck 57. The buffer space 55 is provided between the showerhead 56 and the electrode 53.

A gas outlet 59 is connected to one lower side of the chamber 64, and a pump 60 is connected to the gas outlet 59 through an exhaust pipe 61. A pressure control valve 63 is installed between the gas outlet 59 and the pump 60.

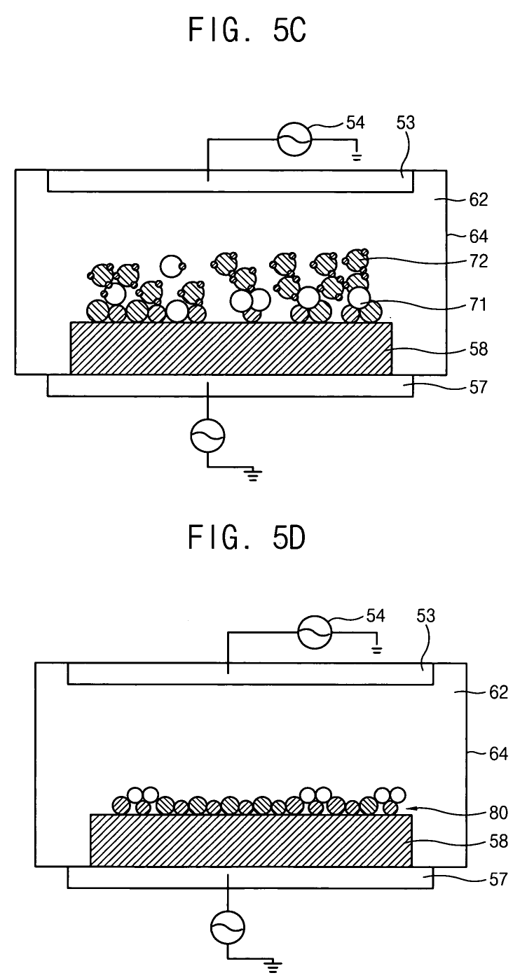

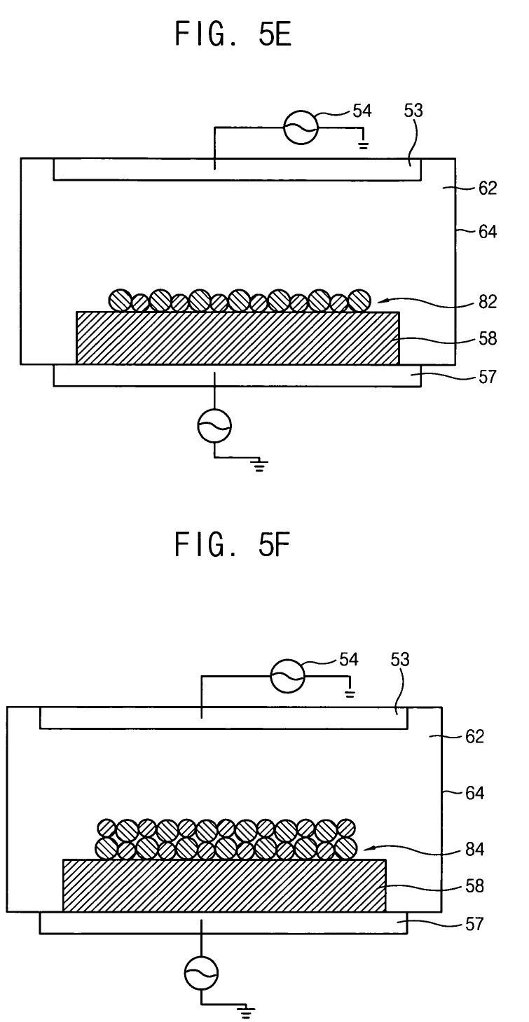

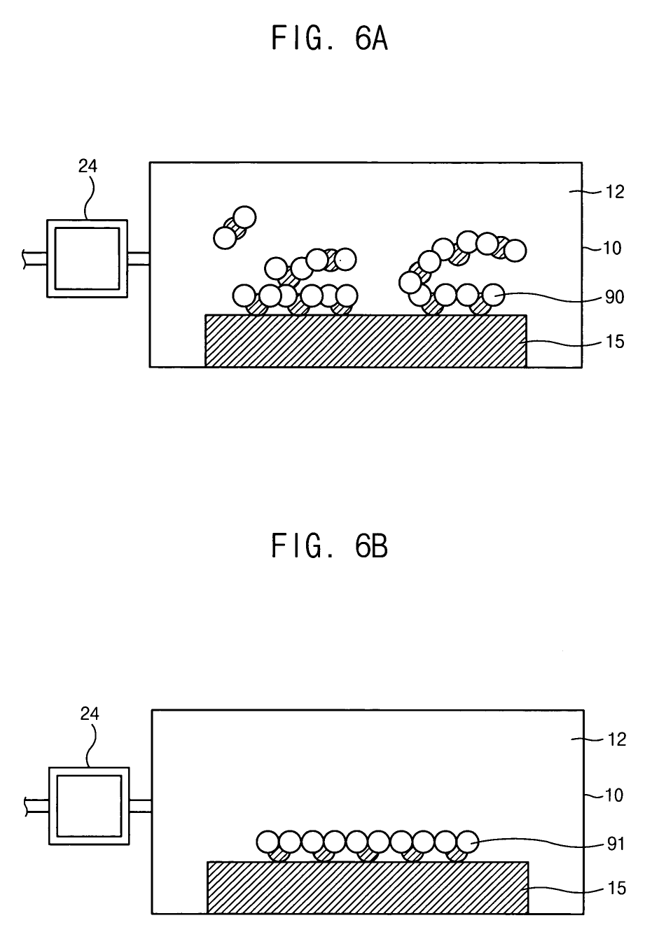

FIGS. 5A to 5F are cross sectional views illustrating a method of forming a layer using the apparatus in FIG. 4 in accordance with an exemplary embodiment of the present invention.

Referring to FIGS. 4 and 5A, after the substrate 58 is loaded onto the chuck 57 installed in the chamber 64, a first reactant 70 or a gas including the first reactant 70 is introduced into the reaction space 62 through the gas supply member 52.

The first reactant 70 may include an organic precursor. Examples of the organic precursor include, but are not limited to, an alkoxide compound, an amide compound, and a cyclopentadienyl compound. These can be used alone or in a mixture thereof.

Examples of the alkoxide compound include, but are not limited to, B[OCH₃]₃, B[OC₂H₅]₃, Al[OCH₃]₃, Al[OC₂H₅]₃, Al[OC₃H₇]₃, Ti[OCH₃]₄, Ti[OC₂H₅]₄, Ti[OC₃H₇]₄, Zr[OC₃H₇]₄, Zr[OC₄H₉]₄, Zr[OC₄H₈OCH₃]₄, Hf[OC₄H₉]₄, Hf[OC₄H₈OCH₃]₄, Hf[OSi(C₂H₅)₃]₄, Hf[OC₂H₅]₄, Hf[OC₃H₇]₄, Hf[OC₄H₉]₄, Hf[OC₅H₁₁]₄, Si[OCH₃]₄, Si[OC₂H₅]₄, Si[OC₃H₇]₄, Si[OC₄H₉]₄, HSi[OCH₃]₃, HSi[OC₂H₅]₃, Si[OCH₃]₃F, Si[OC₂H₅]₃F, Si[OC₃H₇]₃F, Si[OC₄H₉]₃F, Sn[OC₄H₉]₄, Sn[OC₃H₇]₃[C₄H₉], Pb[OC₄H₉]₄, Pb₄O[OC₄H₉]₆, Nb[OCH₃]₅, Nb[OC₂H₅]₅, Nb[OC₃H₇]₅, Nb[OC₄H₉]₅, Ta[OCH₃]₅, Ta[OC₂H₅]₅, Ta[OC₄H₉]₅, Ta(OC₂H₅)₅, Ta(OC₂H₅)₅[OC₂H₄N(CH₃)₂], P[OCH₃]₃, P[OC₂H₅]₃, P[OC₃H₇]₃, P[OC₄H₉]₃, and PO[OCH₃]₃. These can be used alone or in a mixture thereof.

Examples of the amide compound include, but are not limited to, Ti(NC₂H₆)₄, Ti(NC₄H₁₀)₄, Hf(NC₂H₆)₄, Hf(NC₂H₆)₄, Hf(NC₃H₈)₄, Zr(NC₂H₈)₄, HSi(NC₂H₆)₃. These can be used alone or in a mixture thereof.

Examples of the cyclopentadienyl compound include, but are not limited to, Ru(Cp)₂ (wherein, “Cp” represents a cyclopentadienyl group), Ru(CpC₂H₅)₂, Ru(CPC₃H₇)₂, La(CpC₃H₇)₃, Ru(CpC₄H₉)₂, Y(CpC₄H₉)₃, and La(CpC₄H₉)₃. These can be used alone or in a mixture thereof.

The first reactant 70 is partially chemisorbed to the substrate 58 after the first reactant 70 is introduced into the reaction space 62, thereby forming an adsorption layer 71 on the substrate 58.

Referring to FIGS. 4 and 5B, a purge gas is introduced into the chamber 64 to remove a non-chemisorbed first reactant 70 from the chamber 64. Hence, the adsorption layer 71 is completed on the substrate 58. The non-chemisorbed first reactant 70 may include a physisorbed first reactant 70 to the substrate 58 and/or a drifting first reactant 70 in the reaction space 62.

After the purge gas is provided into the reaction space 62, the non-chemisorbed first reactant 70 is removed from the chamber 10 through the gas outlet 59 and the exhaust pipe 61 by operating the pump 60. When the purge gas is introduced into the chamber 10, the pressure control valve 63 is closed. After the purge gas ventilates the chamber 10, the pressure control valve 63 is opened. Thus, all or substantially all of the non-chemisorbed first reactant 70 is removed from the chamber 10 by pumping out the non-chemisorbed first reactant 70 from the chamber 64.

In an exemplary embodiment of the present invention, the purge gas may have a plasma phase. That is, when the purge gas is introduced into the chamber 64, the RF power is simultaneously applied to the purge gas so that the purge gas is excited to form a plasma.

Referring to FIGS. 4 and 5C, after the non-chemisorbed first reactant 70 is removed from the reaction space 62, a second reactant 72 or a gas including the second reactant 72 is introduced into the reaction space 62 of the chamber 64.

The second reactant 72 may include an oxygen-containing compound or a nitrogen-containing compound. Examples of the second reactant 72 include, but are not limited to, oxygen (O₂), nitrous oxide (N₂O), nitrogen (N₂), and ammonia (NH₃). These can be used alone or in a mixture thereof.

When the second reactant 72 is provided onto the adsorption layer 71, the second reactant 72 is chemically reacted with the adsorption layer 71 to thereby form a preliminary layer 80 on the substrate 58. The preliminary layer 80 includes, but is not limited to, oxide, nitride, and oxynitride.

In an exemplary embodiment of the present invention, the second reactant 72 may have a plasma phase. Namely, when the second reactant 72 is introduced into the chamber 64, the RF power is simultaneously applied to the second reactant 72, thereby exciting the second reactant into the plasma phase. Thus, the reaction between the first reactant 70 chemisorbed to the substrate 58 and the second reactant 72 may be promoted to more stably form the preliminary layer 80 on the substrate 15.

Referring to FIGS. 4 and 5D, a gas for removing impurities is introduced into the chamber 64. In particular, after the gas for removing impurities is introduced into the buffer space 55 through the gas supply member 51, an RF power is applied from the RF power source 54 to the electrode 53 so that the gas for removing impurities is excited to form a plasma for removing impurities.

The gas for removing impurities may include an inert gas or an inactive gas that may not react with the first and the second reactants 70 and 72 remaining in the chamber 64. Alternatively, the gas for removing impurities may include a mixture of an inert gas or an inactive gas. These gases may effectively remove the impurities from the preliminary layer 80 without producing by-products.

Examples of the inert gas include, but are not limited to, a helium (He) gas, a xenon (Xe) gas, a krypton (Kr) gas, and an argon (Ar) gas. These can be used alone or in a mixture thereof.

Examples of the inactive gas include, but are not limited to, an oxygen (O₂) gas, a hydrogen (H₂) gas, an ammonia (NH₃) gas, a nitrous oxide (N₂O) gas, and a nitrogen dioxide (NO₂) gas. These can be used alone or in a mixture thereof.

When the RF power is applied to the gas for removing impurities, the plasma for removing impurities is generated in the buffer space 55, and then the plasma for removing impurities is uniformly provided onto the preliminary layer 80 formed on the substrate 58 through the showerhead 56.

Referring to FIGS. 4 and 5E, the plasma for removing impurities is chemically reacted with the impurities in the preliminary layer 80, thereby removing the impurities from the preliminary layer 80. At this time, the plasma for removing impurities also removes the non-chemisorbed second reactant 72 from the chamber 64. When the impurities are removed from the preliminary layer 80, a layer 82 having low impurity content is formed on the substrate 58.

Referring to FIGS. 4 and 5F, a layer structure 84 having a desired thickness is formed on the substrate 58 by repeating introducing the first reactant 70, removing the non-chemisorbed first reactant 70, introducing the second reactant 72, and removing the impurities from the desired layer 80.

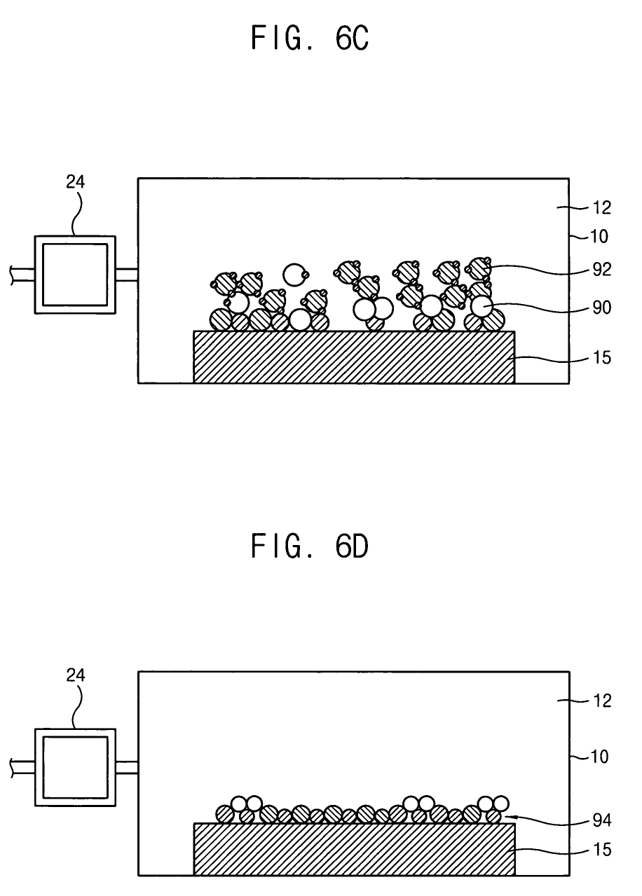

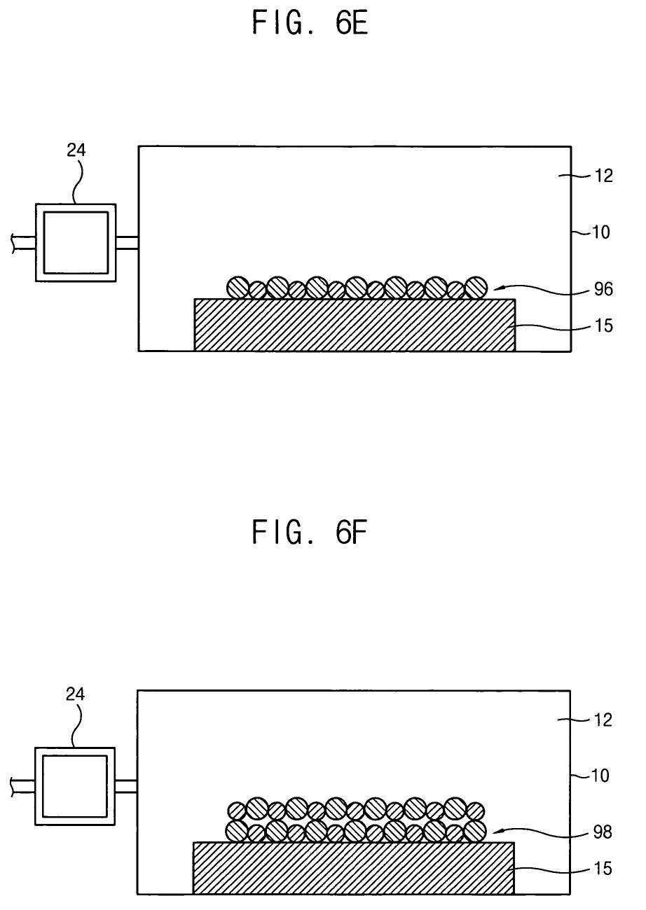

FIGS. 6A to 6F are cross sectional views illustrating a method of forming a layer using the apparatus in FIG. 2 in accordance with an exemplary embodiment of the present invention.

Referring to FIGS. 2 and 6A, the substrate 15 loaded into the chamber 10, and then a first reactant 90 or a first gas including the first reactant 90 is introduced into the reaction space 12 of the chamber 10 through the introducing member 16. The first reactant 90 may include an organic precursor.

The first reactant 90 is partially chemisorbed onto the substrate 15 after the first reactant 90 is provided onto the substrate 15 so that an adsorption layer 91 is formed on the substrate 15.

As shown in FIGS. 2 and 6B, a first purge gas introduced into the reaction space 12 of the chamber 10 to remove a non-chemisorbed first reactant 90 from the chamber 10. The non-chemisorbed first reactant 90 may include a physisorbed first reactant 90 to the substrate 15 and/or a drifting first reactant 90 in the chamber 10. The first purge gas and the non-chemisorbed first reactant 90 are exhausted from the chamber 10 through the exhaust pipe by operating the pressure control valve 21 and the pump 23. When the first purge gas removes the non-chemisorbed first reactant 90, the pressure control valve 21 is closed. Then, the pressure valve 21 is opened and the pump 23 is operated so that the first purge gas and the non-chemisorbed first reactant 90 are exhausted from the chamber 10. Here, all or substantially all of the non-chemisorbed first reactant 90 may be removed from the chamber 10.

In an exemplary embodiment of the present invention, the first purge gas may have a plasma phase. That is, the first purge gas is excited to thereby have a plasma phase in a remote plasma generator 24 installed on the outside of the chamber 10, and then the first purge gas having the plasma phase is introduced into the chamber 10.

Referring to FIGS. 2 and 6C, after the non-chemisorbed first reactant 90 is removed from the reaction space 12, a second reactant 92 or a second gas including the second reactant 92 is introduced into the reaction space 12 of the chamber 10. The second reactant 92 may include an oxygen-containing compound or a nitrogen-containing compound.

Referring to FIGS. 2 and 6D, when the second reactant 92 is provided onto the layer 91, the second reactant 92 is chemically reacted with reactants in the adsorption layer 91 formed on the substrate 15 to thereby form a preliminary layer 94 on the substrate. The preliminary layer 94 includes, but is not limited to, oxide, nitride, and oxynitride.

In an exemplary embodiment of the present invention, the second reactant 92 may have a plasma phase. Namely, the second reactant 92 may be excited to have the plasma phase in the remote plasma generator 24 installed the outside of the chamber 10, and then the second reactant 92 having the plasma phase is introduced into the chamber 10. Thus, the reaction between the chemisorbed first reactant 90 and the second reactant 92 may be promoted to more stably form the preliminary layer 94 on the substrate 15.

Referring now to FIG. 6D, impurities that are previously contained in the adsorption layer and not reacted with the second reactant 92 still remain in the layer 94.

In order to remove the impurities from the layer 94, a plasma for removing impurities is introduced into the chamber 10 through the introducing portion 16. The plasma for removing impurities may be formed in the remote plasma generator 24. Alternatively, a plasma for removing impurities is generated in the buffer space 55 according to the application of the RF power to a gas for removing impurities, and then the plasma for removing impurities is uniformly provided onto the preliminary layer 94 substrate 58 through the showerhead 56.

Referring to FIGS. 2 and 6E, the plasma for removing impurities is chemically reacted with the impurities contained in the preliminary layer 94, thereby removing the impurities from the preliminary layer 94. As a result, a layer having a low impurity content is formed on the substrate 15. At this time, the plasma for removing impurities may also remove the non-chemisorbed second reactant 92 from the chamber 10.

Referring to FIGS. 2 and 6F, a layer structure 98 having a desired thickness is formed by repeatedly introducing the first reactant 90, removing the non-chemisorbed first reactant 90, introducing the second reactant 92, and removing the impurities from the preliminary layer 94.

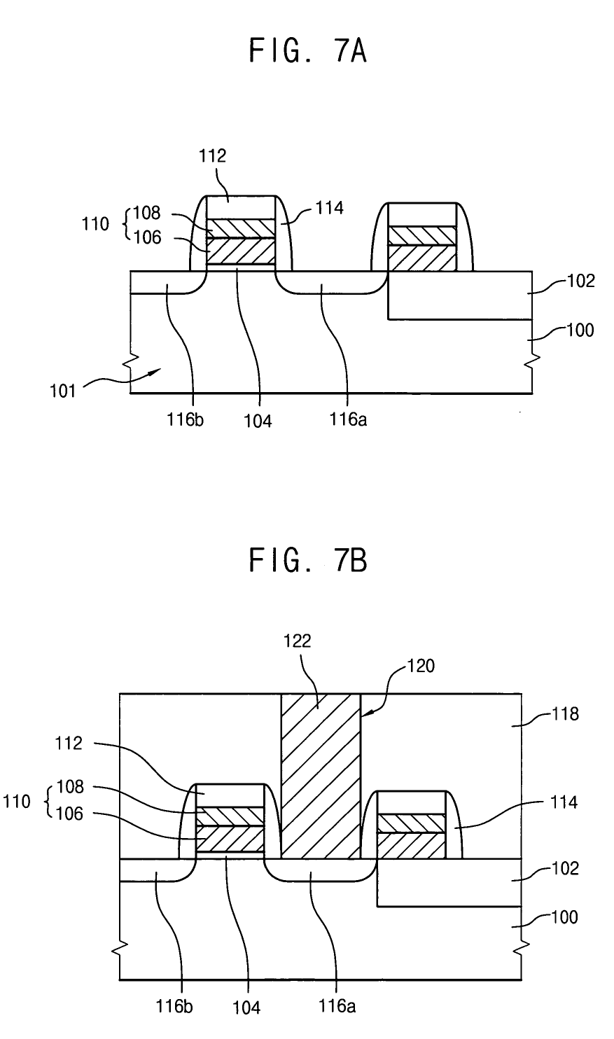

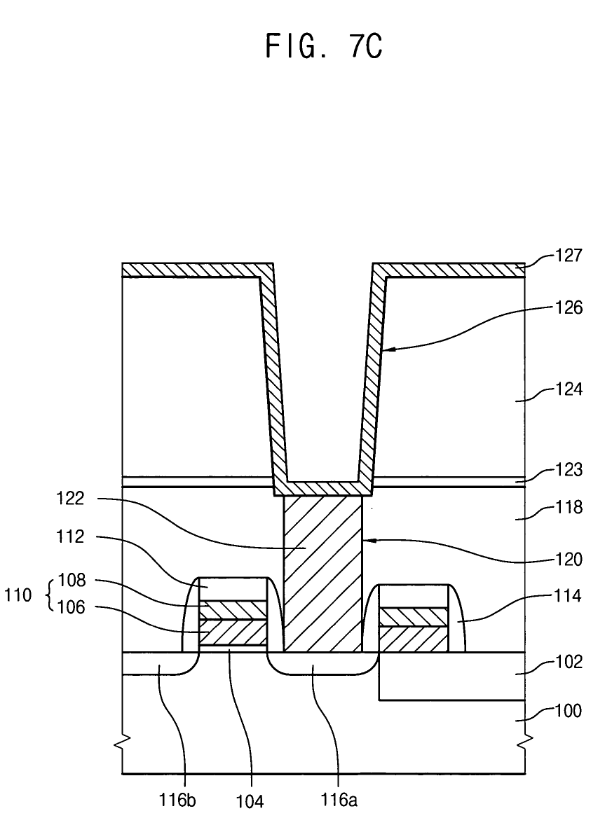

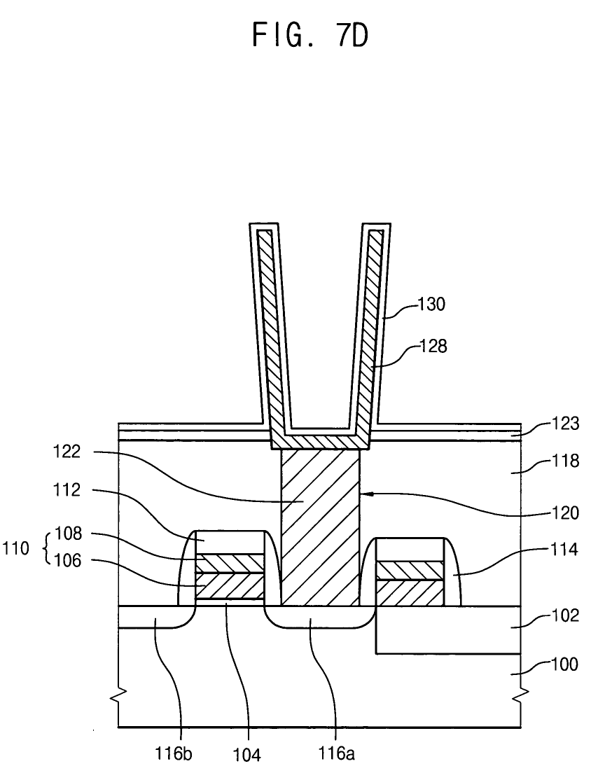

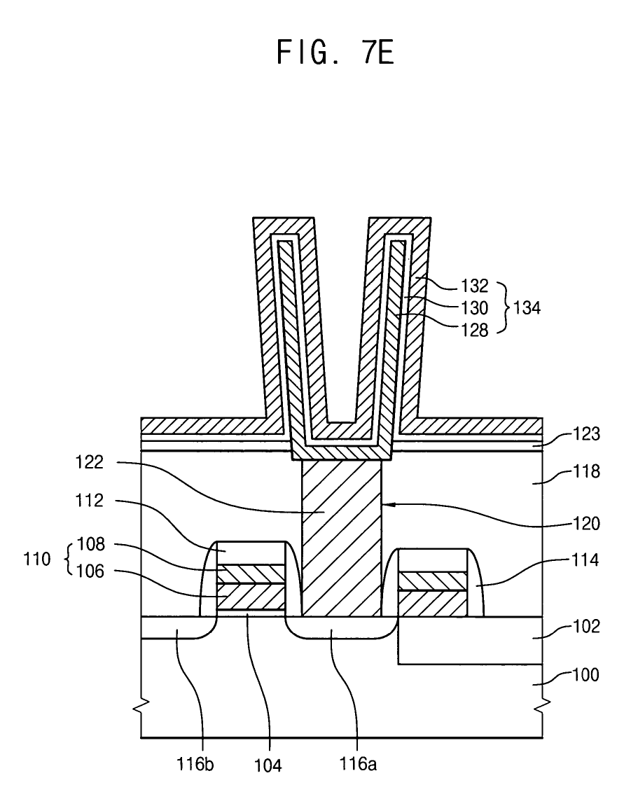

FIGS. 7A to 7E are cross sectional views illustrating a method of forming a capacitor of a semiconductor device in accordance with an exemplary embodiment of the present invention.

Referring to FIG. 7A, an active region 101 and a field region 102 are defined on a semiconductor substrate 100 by an isolation process such as a shallow trench isolation (STI) process.

A transistor including a gate insulation layer 104, a gate electrode 110 and source/drain regions 116a and 116b is formed on the substrate 100. When a semiconductor device has a memory capacity of about 1 gigabit or more, the gate insulation layer 104 may have a thickness of about 10 Å or less.

The gate insulation layer 104 may be formed using an ALD process. In particular, an insulation layer is formed by processes substantially identical to the processes described with reference to FIGS. 5A to 5F or FIGS. 6A to 6F. Then, impurities in the insulation layer are removed using a plasma for removing impurities to thereby complete the gate insulation layer 104 including metal oxide on the substrate 100. The gate electrode 110 may have a polycide structure including a doped polysilicon layer 106 and a metal silicide layer 108.

A capping layer 112 and a spacer 114 are formed on an upper face and a sidewall of the gate electrode 110, respectively. The capping layer 112 and the spacer 114 may include silicon oxide or silicon nitride.

Referring to FIG. 7B, a first insulation layer 118 is formed on the substrate 100 on which the transistor is formed. The first insulation layer 118 may include oxide. A contact hole 120 partially exposing the source/drain regions 116a and 116b is formed by partially etching the first insulation layer 118 using a photolithography process. Then, a contact plug 122 is formed in the contact hole 120 by depositing polysilicon doped with phosphorous (P) after a first conductive layer is formed on the first insulation layer 118 to fill up the contact hole 120 and partially removing the first conductive layer. Here, an upper portion of the first conductive layer is removed using an etch back process or a chemical mechanical polishing (CMP) process to thereby form the contact plug 122 in the contact hole 120.

Referring to FIG. 7C, an etch stop layer 123 is formed on the contact plug 122 and the first insulation layer 118. The etch stop layer 123 may include a material having a high etching selectivity with respect to the first insulation layer 118. For example, the etch stop layer 123 may include silicon nitride or silicon oxynitride.

A second insulation layer 124, typically including oxide, is formed on the etch stop layer 123, and then partially etched to form an opening 126 to expose the contact plug 122. In particular, the second insulation layer 124 is partially etched until the etch stop layer 123 is exposed. Then, the etch stop layer 123 is partially etched to form the opening 126 that exposes the contact plug 122 and a portion of the first insulation layer 118 around the contact plug 122. The opening 126 may be formed with an inclination resulting from a bottom portion of the opening 126 narrower than the upper portion thereof. This shape may be obtained in part due to a loading effect during the etch process in which the etch rate at the bottom portion is slower than that at the upper portion of the opening 126.

A second conductive layer 127 is formed on a sidewall and a bottom portion of the opening 126, and on the second insulation layer 124. The second conductive layer 127 may include a conductive material such as doped polysilicon, a metal such as ruthenium (Ru), platinum (Pt) and iridium (Ir), a conductive metal nitride such as titanium nitride (TiN), tantalum nitride (TaN) and tungsten nitride (WN), or a combination of two or more of these materials.

Referring to FIG. 7D, a sacrificial layer (not shown) is formed on the second conductive layer 127 and the opening 126. An upper portion of the sacrificial layer is then etched back so that the second conductive layer 127 may remain on the sidewall and the bottom portion of the opening 126. The second conductive layer 127 formed on the second insulation layer 124 is removed. The second conductive layer 127 formed along the profile of the inner portion of the opening 126 is then separated with the cell unit to form a lower electrode 128 of a capacitor at each cell region. Then, the sacrificial layer may be removed using a wet etching process. The lower electrode 128 may be formed to have a generally cylindrical shape in which an inlet portion is relatively wide and a bottom portion is relatively narrow.

Subsequently, a dielectric layer 130 of a capacitor is formed on the lower electrode 128 using an organic precursor such as an alkoxide compound, an amide compound and a cyclopentadienyl compound as a first reactant, and an oxygen-containing compound or a nitrogen-containing compound such as oxygen (O₂), nitrous oxide (N₂O) and nitrogen (N₂) as a second reactant as described with reference to FIGS. 5A to 5F and 6A to 6F.

Impurities included in the dielectric layer 130 are removed using a plasma for removing impurities. The impurities, such as ligands having carbons included in the first reactant and remain in the dielectric layer 130, are removed to thereby obtain the dielectric layer 130 having a greatly reduced leakage current. The dielectric layer 130 may be formed as a single layer or may be formed as a composite layer including two or more layers of metal oxides that are alternately deposited. For example, the dielectric layer 130 may be formed by alternately depositing the layers of Al₂O₃ and HfO₂ according to change of the precursors introduced into the chamber during the ALD process.

Referring to FIG. 7E, when an upper electrode 132 is formed on the dielectric layer 130, a capacitor 134 including the lower electrode 128, the dielectric layer 130 and the upper electrode 132 is formed over the substrate 100. The upper electrode 132 may be formed using a conductive material that includes polysilicon, a metal such as ruthenium (Ru), platinum (Pt) and iridium (Ir), or a conductive metal nitride such as TiN, TaN and WN. Alternatively, the upper electrode may include at least one layer formed using a compound of the conductive materials. For example, the upper electrode 132 has a stacked structure in which a polysilicon layer is formed on the dielectric layer 130 and a titanium nitride layer is formed on the polysilicon layer.

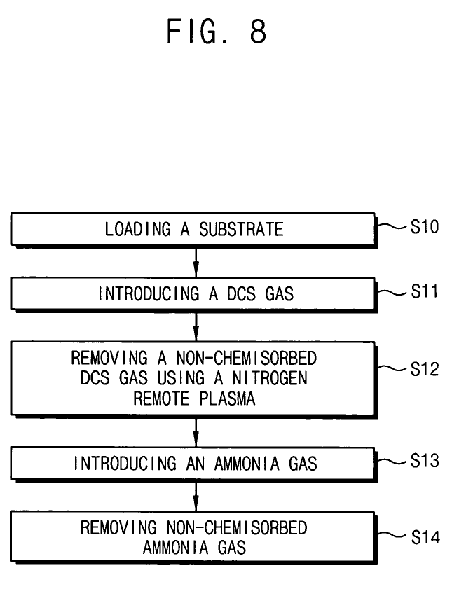

FIG. 8 is a flow chart illustrating a method of forming a layer according to an exemplary embodiment of the present invention. In the present embodiment, a silicon nitride (SiN) layer is formed on a substrate using an ALD process as described above. For example, the silicon nitride layer is formed at a temperature of about 550° C. A DCS (SiCl₂H₂) gas and an ammonia (NH₃) gas are provided onto the substrate as a first reactant and a second reactant, respectively. Here, a flow rate ratio between the ammonia gas and the DCS gas is about 4.5:1. The ammonia gas may be provided onto the substrate using a remote plasma generator.

Referring to FIG. 8, the substrate including silicon is loaded into a chamber in step S10. When the DCS gas is introduced into the chamber for about 20 seconds as the first reactant in step S11, the DCS gas is partially chemisorbed to the substrate so that a preliminary layer is formed on the substrate. The preliminary layer may include silicon. After the preliminary layer is formed on the substrate, the chamber is primarily vacuumized for about 10 seconds using a pump.

In step S12, after a nitrogen (N₂) gas is activated in the remote plasma generator, the nitrogen gas is converted into a nitrogen remote plasma. The nitrogen remote plasma is introduced into the chamber for about 10 seconds. The nitrogen remote plasma removes a non-chemisorbed DCS gas from the chamber, and also removes hydrogens from the preliminary layer formed on the substrate. That is, the nitrogen remote plasma purges the chamber to remove the non-chemisorbed DCS gas from the chamber as well as removes impurities such as hydrogen from the preliminary layer.

In step S13, an ammonia gas activated by the remote plasma generator is introduced into the chamber for about 35 seconds as the second reactant. When the ammonia gas is provided onto the preliminary layer, the ammonia gas is partially chemisorbed to the preliminary layer, thereby forming a desired layer on the substrate. Namely, the silicon nitride layer is finally formed on the substrate by chemically reacting the ammonia gas with reactants in the preliminary layer.

In step 14, a non-chemisorbed ammonia gas is removed from the chamber by providing an inactive gas into the chamber for about 10 seconds, thereby completing the desired layer on the substrate. The inactive gas may include a nitrogen (N₂) gas.

Subsequently, the chamber is secondarily vacuumized using the pump for about 10 seconds so that all or substantially all of remaining gases in the chamber are completely removed from the chamber.

Table 1 shows the processing time for forming the layer using the DSC and the ammonia gases in accordance with an exemplary embodiment of the present invention.

TABLE 1

| | processing | flow rate | |
|---|---|---|---|
| | time (sec) | (slm) | plasma |
| introducing DCS gas | 20 | 1 | |
| primarily vacuumizing chamber | 10 | 0 | |
| removing unreacted DCS gas | 10 | 2 | on |
| introducing ammonia gas | 35 | 4.5 | on |
| removing unreacted ammonia gas | 10 | 2 | |
| secondarily vacuumizing chamber | 10 | 0 | |

As shown in Table 1, the flow rate ratio between the DCS gas and the ammonia gas is about 1:4.5. However, a time ratio of introducing the DCS gas relative to the ammonia gas is about 2:3.5. In addition, a flow rate ratio between the nitrogen remote plasma and the inactive gas is about 1:1. Meanwhile, purge gas or plasma is not introduced into the chamber in either of the two vacuumizing steps.

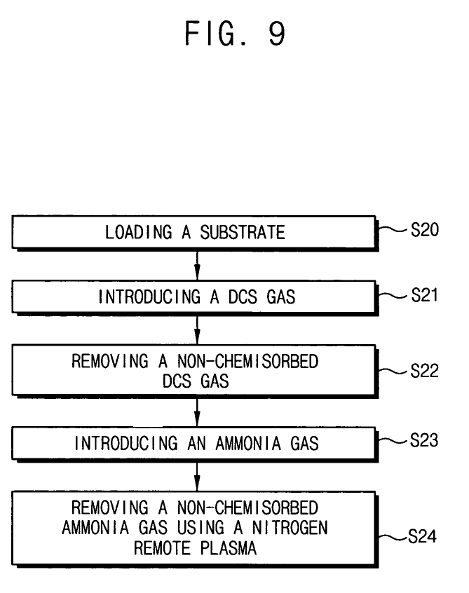

FIG. 9 is a flow chart explaining a method of forming a layer according to an exemplary embodiment of the present invention. In the present embodiment, a silicon nitride layer is formed on a substrate using an ALD process at a temperature of about 550° C. A DCS gas and an ammonia gas are used as a first reactant and a second reactant, respectively. A flow rate ratio between the ammonia gas and the DCS gas is about 4.5:1. The ammonia gas is provided using a remote plasma generator.

Referring to FIG. 9, the substrate including silicon is loaded into a chamber in step S20. In step S21, the DCS gas is introduced into the chamber about 20 seconds as the first reactant. When the DCS gas is provided onto the substrate, the DCS gas is partially chemisorbed to the substrate, thereby forming an adsorption layer on the substrate.

In step S22, a non-chemisorbed DCS gas is removed from the chamber by introducing an inactive gas such as a nitrogen gas into the chamber for about 3 seconds. The non-chemisorbed DCS gas may include physically absorbed DCS gas and a drifting DCS gas in the chamber. Then, the chamber is primarily vacuumized for about 4 seconds using a pump so that all or substantially all of remaining DCS gas is removed from the chamber.

In step S23, the ammonia gas activated by the remote plasma generator is introduced into the chamber for about 35 seconds as the second reactant. When the ammonia gas is provided onto the adsorption layer positioned on the substrate, the ammonia gas is partially chemisorbed to the adsorption layer. Hence, a preliminary layer is formed on the substrate by chemically reacting the ammonia gas with reactants in the adsorption layer. The preliminary layer may include silicon nitride. Then, the chamber is secondarily vacuumized for about 4 seconds to remove remaining ammonia gas from the chamber.

In step S24, a nitrogen remote plasma generated in the remote plasma generator is introduced into the chamber to completely remove the non-chemisorbed ammonia gas and also to remove impurities such as hydrogens contained in the preliminary layer, thereby forming a layer on the substrate. The layer may include silicon nitride and has low hydrogen content. The nitrogen remote plasma not only removes the non-chemisorbed ammonia gas from the chamber but also removes hydrogen in the preliminary layer of silicon nitride formed on the substrate. Therefore, the layer may include silicon nitride and has low hydrogen content. For example, the nitrogen remote plasma treatment is performed for about 10 seconds.

Table 2 shows the processing time for forming the layer using the DSC and the ammonia gases in accordance an exemplary embodiment of the present invention.

TABLE 2

| | processing | flow rate | |
|---|---|---|---|
| | time (sec) | (slm) | plasma |
| introducing DCS gas | 20 | 1 | |
| Removing unreacted DCS gas | 3 | 2 | |
| primarily vacuumizing chamber | 4 | 0 | |
| introducing ammonia gas | 35 | 4.5 | on |
| secondarily vacuumizing chamber | 4 | 0 | |
| Removing unreacted ammonia gas | 10 | 2 | on |

Referring to Table 2, the flow rate ratio between the DCS gas and the ammonia gas is about 1:4.5, however, a time ratio of introducing the DCS gas relative to that of the ammonia gas is about 2:3.5. Additionally, a flow rate ratio between the inactive gas and the nitrogen remote plasma is about 1:1. As described above, purge gas or plasma is not introduced into the chamber in the primarily and secondarily vacuumizing steps.

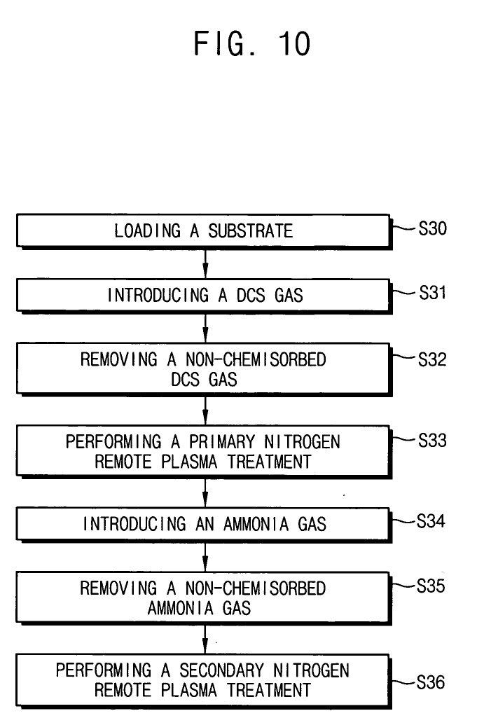

FIG. 10 is a flow chart explaining a method of forming a layer according to an exemplary embodiment of the present invention. In the present embodiment, a silicon nitride layer is formed on a substrate using an ALD process at a lo temperature of about 550° C. A DCS gas and an ammonia gas are used as a first reactant and a second reactant, respectively. A flow rate ratio of the ammonia gas relative to the DCS gas is about 4.5:1. The ammonia gas is provided using a remote plasma generator.

Referring to FIG. 10, the substrate of silicon is loaded into a chamber in step S30. The DCS gas is introduced into the chamber for about 20 seconds as the first reactant in step S31. The DCS gas is provided onto the substrate to be partially chemisorbed to the substrate, thereby forming an adsorption layer on the substrate. The adsorption layer may correspond to a silicon layer.

In step S32, a non-chemisorbed DCS gas is removed from the chamber by introducing a first inactive gas such as a nitrogen gas into the chamber for about 3 seconds. After the first inactive gas removes the non-chemisorbed DCS gas from the chamber, the chamber is primarily vacuumized for about 4 seconds using a pump. In the step of primarily vacuumizing the chamber, all or substantially all of remaining DCS gas is removed from the chamber.

In step S33, a first nitrogen remote plasma generated in the remote plasma generator is introduced into the chamber. The first nitrogen remote plasma is converted from a nitrogen gas in the remote plasma generator. The first nitrogen remote plasma removes hydrogens contained in the adsorption layer form the adsorption layer. The first nitrogen remote plasma treatment is carried out for about 10 seconds.

In step S34, the ammonia gas activated by the remote plasma generator is introduced into the chamber for about 35 seconds as the second reactant. The ammonia gas is partially chemisorbed to the adsorption layer to thereby form a preliminary layer on the substrate. That is, the ammonia gas is chemically reacted with reactants in the adsorption layer to form the preliminary layer on the substrate. The preliminary layer may include silicon nitride.

In step S35, a non-chemisorbed ammonia gas is removed from the chamber by providing a second inactive gas such as a nitrogen gas for about 3 seconds. Then, the chamber is secondarily vacuumized for about 4 seconds using the pump. As a result, all or substantially all of remaining ammonia gas is removed from the chamber.

In step S36, a second nitrogen remote plasma generated in the remote plasma generator is introduced into the chamber. The second nitrogen remote plasma removes hydrogens contained in the preliminary layer so that a layer is formed on the substrate. Thus, the layer of silicon nitride may have extremely low hydrogen content. The second nitrogen remote plasma treatment is carried out for about 10 seconds.

Table 3 shows the processing time for forming the layer using the DSC and the ammonia gases in accordance an exemplary embodiment of the present invention.

TABLE 3

| | | flow | |
|---|---|---|---|
| | processing | rate | |
| | time (sec) | (slm) | plasma |
| introducing DCS gas | 20 | 1 | |
| Removing unreacted DCS gas | 3 | 2 | |
| primarily vacuumizing chamber | 4 | 0 | |
| primary nitrogen remote plasma treatment | 10 | 2 | on |
| introducing ammonia gas | 35 | 4.5 | |
| Removing unreacted ammonia gas | 3 | 2 | |
| secondarily vacuumizing chamber | 4 | 0 | |
| secondary nitrogen remote plasma | 10 | 2 | on |
| treatment | | | |

As shown in Table 3, the processing time and the flow rate in the first nitrogen remote plasma treatment are substantially identical to those of the second nitrogen remote plasma treatment. Additionally, the unreacted DCS gas and the unreacted ammonia gas are removed by providing the first inert gas and the second inert gas for a substantially identical period of time. Here, the flow rate ratio between the first inert gas and the second inert gas is about 1:1.

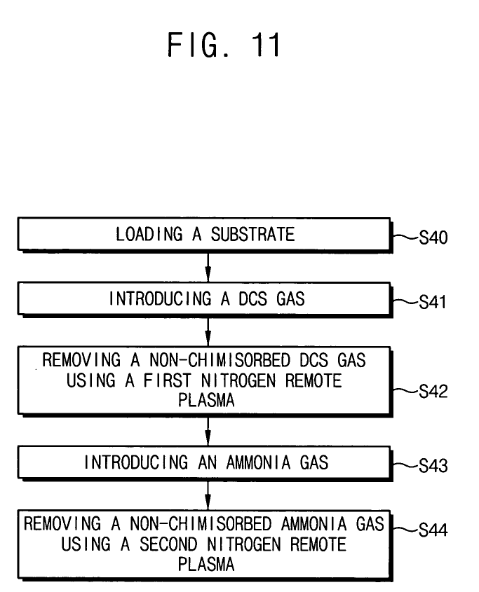

FIG. 11 is a flow chart for explaining a method of forming a layer according to an exemplary embodiment of the present invention. In the present embodiment, a silicon nitride layer is formed on a substrate using an ALD process at a temperature of about 550° C. A DCS gas and an ammonia gas are used as a first reactant and a second reactant, respectively. A flow rate ratio of the ammonia gas relative to the DCS gas is about 4.5:1. The ammonia gas is provided using a remote plasma generator.

Referring to FIG. 11, the substrate of silicon is loaded into a chamber in step S40. When the DCS gas is introduced in the chamber for about 20 seconds in step S41, the DCS gas is partially chemisorbed to the substrate to thereby form an adsorption layer on the substrate. The adsorption layer may include silicon.

In step S42, a first nitrogen remote plasma generated in the remote plasma generator is provided into the chamber. The first nitrogen remote plasma purges a non-chemisorbed DCS gas from the chamber as well as removes impurities such as hydrogens from the adsorption layer. The first nitrogen remote plasma treatment is carried out for about 10 seconds. Then, the chamber is primarily vacuumizied for about 4 seconds using a pump. As a result, all or substantially all of remaining DCS gas in the chamber is removed from the chamber.

In step S43, the ammonia gas activated in the remote plasma generator is provided onto the adsorption layer for about 35 seconds as the second reactant. When the ammonia gas is provided in the chamber, the ammonia gas is partially chemisorbed to reactants in the adsorption layer so that a preliminary layer is formed on the substrate. The preliminary layer may include silicon nitride. Particularly, the preliminary layer is formed in accordance with the chemical reaction between the ammonia gas and the adsorption layer.

In step S44, a second nitrogen remote plasma generated in the remote plasma generator is introduced into the chamber. The second nitrogen remote plasma purges a non-chemisorbed ammonia gas from the chamber but also removes hydrogens from the preliminary layer formed on the substrate. After the second nitrogen plasma treatment is performed, a layer having extremely low hydrogen content is formed on the substrate. The second nitrogen remote plasma treatment is carried out for about 10 seconds. Then, the chamber is secondarily vacuumized about 4 seconds using the pump. Thus, all or substantially all of remaining ammonia gas in the chamber is removed from the chamber.

Table 4 shows the processing time for forming the layer using the DSC and the ammonia gases in accordance an exemplary embodiment of the present invention.

TABLE 4

| | processing | flow rate | |
|---|---|---|---|
| | time (sec) | (slm) | plasma |
| introducing DCS gas | 20 | 1 | |
| removing unreacted DCS gas | 10 | 2 | on |
| primarily vacuumizing chamber | 4 | 0 | |
| introducing ammonia gas | 35 | 4.5 | on |
| removing unreacted ammonia gas | 10 | 2 | on |
| secondarily vacuumizing chamber | 4 | 0 | |

Referring to Table 4, the processing time of introducing the DCS gas is shorter than that of the ammonia gas by a ratio of about 2:3.5. The unreacted DCS gas and the unreacted ammonia gas are removed from the chamber by providing the nitrogen remote plasma for a substantially identical period of time.

While the above-described embodiments of the present invention disclose that at least one nitrogen remote plasma treatment is applied to the ALD process, it is obvious that the nitrogen remote plasma treatment may also be applied to a chemical vapor deposition (CVD) process to thereby reduce the hydrogen content of a layer formed by the CVD process.

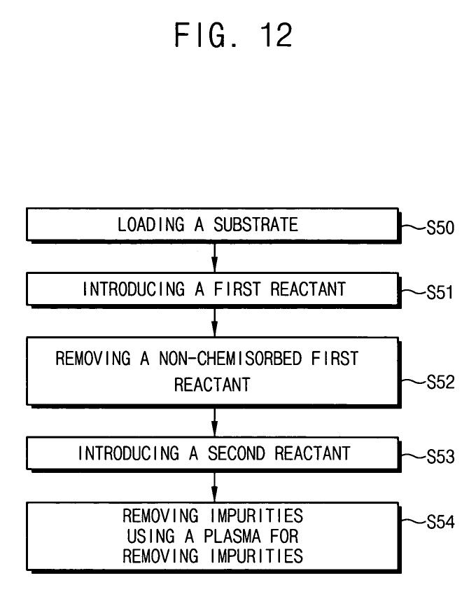

FIG. 12 is a flow chart explaining a method of forming a layer according to an exemplary embodiment of the present invention. In the present embodiment, a layer including an oxide such as hafnium oxide (HfO₂), a nitride or an oxynitride is formed on a substrate at a temperature of about 325° C. under a pressure of about 200 Pa through an ALD process. An organic precursor such as tetrakis ethyl methyl amino hafnium (TEMAH) and an oxygen-containing compound such as ozone (O₃) are used as a first reactant and a second reactant, respectively. Alternatively, a nitrogen-containing compound may be used as the second reactant. A flow rate ratio between the organic precursor and the oxygen-containing compound is about 1:1. For example, a flow rate of the organic precursor is about 1,000 sccm and also a flow rate of the oxygen-containing compound is about 1,000 sccm.

Referring to FIG. 12, the substrate including silicon is loaded into a chamber in step S50. In step S51, the organic precursor is introduced into the chamber for about 2 seconds as the first reactant so that the organic precursor is partially chemisorbed to the substrate. Hence, an adsorption layer is formed on the substrate.

In step S52, a purge gas is introduced into the chamber to remove a non-chemisorbed first reactant from the chamber. The purge gas is provided into the chamber for about 2 seconds.

In step S53, the oxygen-containing compound or the nitrogen-containing compound is introduced into the chamber for about 2 seconds as the second reactant. The oxygen-containing compound or the nitrogen-containing compound is chemically reacted with reactants in the adsorption layer so that a preliminary layer is formed on the substrate. That is, the oxygen-containing compound or the nitrogen-containing compound is partially chemisorbed to the adsorption layer.

In step S54, a plasma for removing impurities such as an argon (Ar) plasma is introduced into the chamber for about 2 seconds. The plasma for removing impurities removes impurities contained in the preliminary layer as well as purges a non-chemisorbed oxygen-containing compound or nitrogen-containing compound from the chamber. The plasma for removing impurities is generated in a remote plasma generator after a gas for generating the plasma is introduced into the remote plasma generator. Alternatively, the plasma for removing impurities may be generated over the substrate by applying an RF power to a gas for generating the plasma. Therefore, the layer having low impurity concentration is formed on the substrate.

Table 5 shows the processing time for forming the layer using the organic precursor and the oxygen-containing compound or the nitrogen-containing compound in accordance an exemplary embodiment of the present invention.

TABLE 5

| | processing | flow rate | |
|---|---|---|---|
| | time (sec) | (sccm) | plasma |
| introducing first reactant | 2 | 1,000 | |
| removing unreacted first reactant | 2 | 1,000 | |
| introducing second reactant | 2 | 1,000 | |
| removing impurities using plasma | 2 | 1,000 | On |

Referring to Table 5, all of the flow rates of the first reactant, the purge gas, the second reactant and the plasma for removing impurities are substantially identical. In addition, all of the processes of introducing the first reactant, removing unreacted first reactant, introducing the second reactant and removing the impurities using the plasma are carried out for a substantially identical period of time.

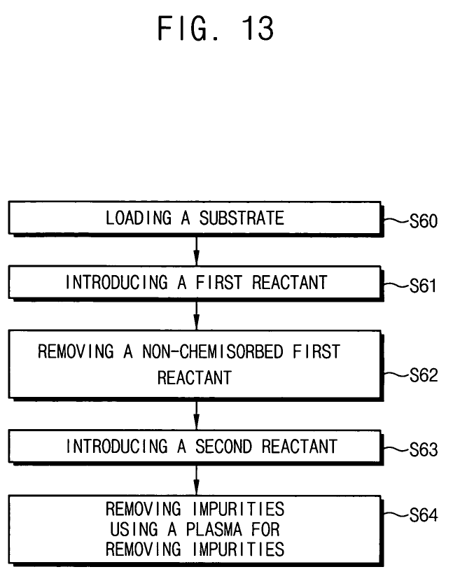

FIG. 13 is a flow chart explaining a method of forming a layer according to an exemplary embodiment of the present invention. In the present embodiment, a layer including a metal oxide such as hafnium oxide (HfO₂), a nitride or an oxynitride is formed on a substrate at a temperature of about 325° C. under a pressure of about 200 Pa using an ALD process. An organic precursor such as tetrakis ethyl methyl amino hafnium (TEMAH) is used as a first reactant, and an oxygen-containing compound such as ozone or a nitrogen-containing compound is used as a second reactant. The flow rate of the organic precursor is substantially identical to that of the oxygen-containing compound or the nitrogen-containing compound. For example, both of the flow rates of the organic precursor and the oxygen-containing compound or the nitrogen-containing compound are about 1,000 sccm.

Referring to FIG. 13, the substrate including silicon is loaded into a chamber in step S60. In step S61, the organic precursor is provided onto the substrate for about 2 seconds as the first reactant so that the organic precursor is partially chemisorbed to the substrate. Thus, an adsorption layer is formed on the substrate.

In step S62, a purge gas is introduced into the chamber to remove a non-chemisorbed organic precursor from the chamber. The purge gas is provided into the chamber for about 2 seconds.

In step S63, the oxygen-containing compound or the nitrogen-containing compound is introduced into the chamber for about 2 seconds as the second reactant. When the oxygen-containing or the nitrogen-containing compound is provided onto the adsorption layer, the oxygen-containing or the nitrogen-containing compound is partially chemisorbed to the adsorption layer to thereby form a preliminary layer on the substrate. Here, after the oxygen-containing or the nitrogen-containing compound is introduced into the chamber, an RF power is applied to the oxygen-containing or the nitrogen-containing compound so that the oxygen-containing or the nitrogen-containing compound has a plasma phase. Alternatively, after the oxygen-containing or the nitrogen-containing compound may have a plasma phase using a remote plasma generator, the oxygen-containing or the nitrogen-containing compound having the plasma phase is introduced into the chamber.

In step S64, a plasma for removing impurities is introduced into the chamber for about 2 seconds. The plasma for removing impurities not only removes impurities contained the preliminary layer but also purges a non-chemisorbed oxygen-containing or nitrogen-containing compound from the chamber. As a result, the layer having low impurity concentration is formed on the substrate.

Table 6 shows the processing time for forming the layer using the organic precursor and the oxygen-containing or the nitrogen-containing compound in accordance an exemplary embodiment of the present invention.

TABLE 6

| | processing | flow rate | |
|---|---|---|---|
| | time (sec) | (sccm) | plasma |
| introducing first reactant | 2 | 1,000 | |
| removing unreacted first reactant | 2 | 1,000 | |
| introducing second reactant | 2 | 1,000 | on |
| removing impurities using plasma | 2 | 1,000 | on |

Referring to Table 6, all of the flow rates and the processing time of the first reactant, the purge gas, the second reactant and the plasma for removing impurities are substantially identical. However, the second reactant having the plasma phase is introduced into the chamber.

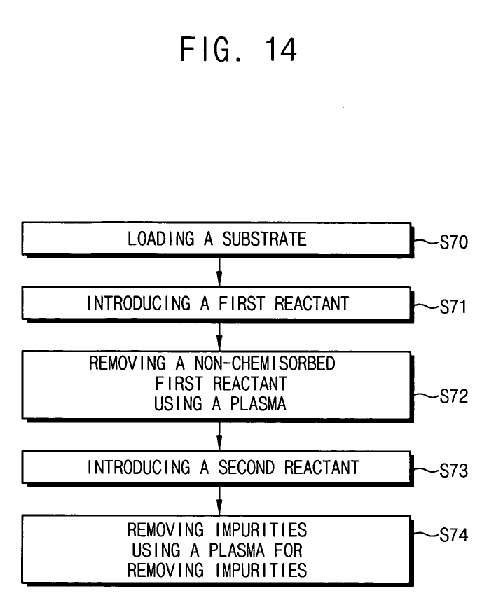

FIG. 14 is a flow chart explaining a method of forming a layer according to an exemplary embodiment of the present invention. In the present embodiment, a layer including an oxide such as hafnium oxide (HfO₂), a nitride or an oxynitride is formed on a substrate at a temperature of about 325° C. under a pressure of about 200 Pa using an ALD process. An organic precursor such as tetrakis ethyl methyl amino hafnium (TEMAH) and an oxygen-containing or a nitrogen-containing compound are used as a first reactant and a second reactant, respectively. The flow rate of the organic precursor is substantially identical to that of the oxygen-containing compound or the nitrogen-containing compound.

For example, both of the flow rates of the organic precursor and the oxygen-containing or the nitrogen-containing compound are about 1,000 sccm.

Referring to FIG. 14, the substrate including silicon is loaded into a chamber in step S70. In step S71, the organic precursor is introduced into the chamber for about 2 seconds as the first reactant so that the organic precursor is partially chemisorbed to the substrate. Therefore, an adsorption layer is formed on the substrate.

In step S72, a purge plasma such as an argon (Ar) plasma is introduced into the chamber to remove a non-chemisorbed organic precursor from the chamber. Here, after a purge gas is introduced into the chamber, an RF power is applied to the purge gas so as to generate the purge plasma over the substrate. Alternatively, a purge plasma may be generated from a purge gas in a remote plasma generator, and then the purge plasma is introduced into the chamber. The purge plasma is provided into the chamber for about 2 seconds.

In step S73, the oxygen-containing or the nitrogen-containing compound is introduced into the chamber for about 2 seconds as the second reactant so that a preliminary layer is formed on the substrate by chemically reacting reactants in the adsorption layer with the oxygen-containing or the nitrogen-containing compound. Here, after the oxygen-containing or the nitrogen-containing compound is introduced into the chamber, an RF power is applied to the oxygen-containing or the nitrogen-containing compound so as to form the oxygen-containing or the nitrogen-containing compound having a plasma phase. Alternatively, the oxygen-containing or the nitrogen-containing compound having a plasma phase is generated in a remote plasma generator, and then the oxygen-containing or the nitrogen-containing compound having the plasma phase is introduced into the chamber.

In step S74, a plasma for removing impurities is introduced into the chamber for about 2 seconds. The plasma for removing impurities not only removes impurities from the preliminary layer but also purges a non-chemisorbed oxygen-containing or the nitrogen-containing compound from the chamber. Thus, the layer having low impurity concentration is formed on the substrate.

Table 7 shows the processing time for forming the layer using the organic precursor and the oxygen-containing or the nitrogen-containing compound in accordance an exemplary embodiment of the present invention.

TABLE 7

| | processing | flow rate | |
|---|---|---|---|
| | time (sec) | (sccm) | plasma |
| introducing first reactant | 2 | 1,000 | |
| Removing unreacted first reactant | 2 | 1,000 | on |
| introducing second reactant | 2 | 1,000 | on |
| Removing impurities using plasma | 2 | 1,000 | on |

As shown in 7, all of the flow rates and the processing time of the first reactant, the purge plasma, the second reactant and the plasma for removing impurities are substantially identical. However, the second reactant having the plasma phase and the purge plasma are introduced into the chamber.

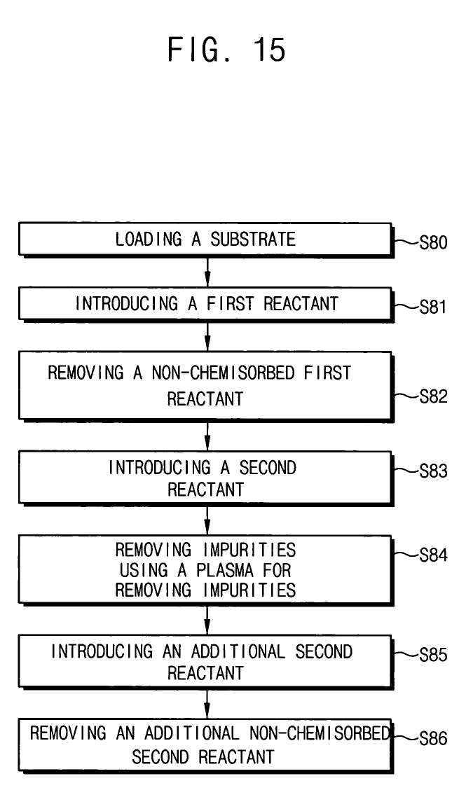

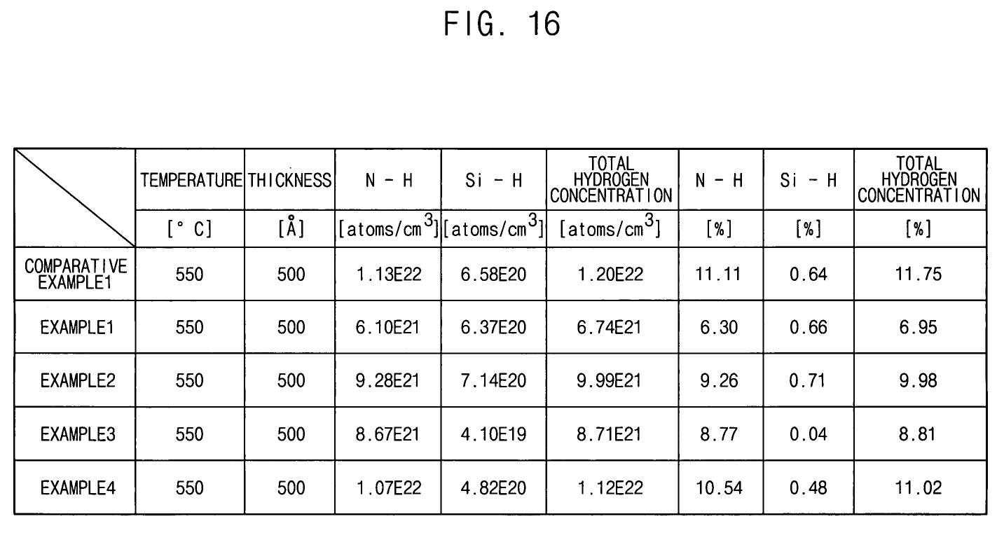

FIG. 15 is a flow chart explaining a method of forming a layer according to an exemplary embodiment of the present invention. In the present embodiment, a layer including an oxide such as hafnium oxide (HfO₂), a nitride or an oxynitride is formed on a substrate at a temperature of about 325° C. under a pressure of about 200 Pa using an ALD process. An organic precursor such as tetrakis ethyl methyl amino hafnium (TEMAH) and an oxygen-containing or a nitrogen-containing compound may be used as a first reactant and a second reactant, respectively. The flow rate of the organic precursor is substantially identical to that of the oxygen-containing or the nitrogen-containing compound. For example, both of the flow rates of the organic precursor and the oxygen-containing or the nitrogen-containing compound are about 1,000 sccm.

Referring to FIG. 15, the substrate including silicon is loaded into a chamber in step S80. In step S81, the organic precursor is introduced into the chamber for about 2 seconds as the first reactant. After the organic precursor is provided onto the substrate, the organic precursor is partially chemisorbed to the substrate, thereby forming an adsorption layer on the substrate.

In step S82, a first purge gas is introduced into the chamber to remove a non-chemisorbed organic precursor from the chamber. The first purge gas is introduced into the chamber for about 2 seconds.

In step S83, the oxygen-containing or the nitrogen-containing compound is introduced into the chamber for about 1 second as the second reactant so that a preliminary layer is formed on the substrate. That is, the oxygen-containing or the nitrogen-containing compound is partially chemisorbed to the adsorption layer to thereby form the preliminary layer on the substrate.

In step S84, a plasma for removing impurities is introduced into the chamber for about 1 second. The plasma for removing impurities removes impurities from the preliminary layer as well as purges a non-chemisorbed oxygen-containing or the nitrogen-containing compound from the chamber.

In step S85, an additional second reactant is introduced into the chamber for about 1 second to reduce the damage to the preliminary layer. The additional second reactant may include an oxygen-containing or a nitrogen-containing compound. When the additional second reactant is partially chemisorbed to the preliminary layer, the preliminary layer may have more stable characteristics.

In step S86, a second purge gas is introduced into the chamber to remove a non-chemisorbed additional second reactant from the chamber. The second purge gas is provided into the chamber for about 1.5 seconds. As a result, the layer having low impurity concentration and improved characteristics is formed on the substrate.

Table 8 shows the processing time for forming the layer using the organic precursor and at least one the oxygen-containing or the nitrogen-containing compound in accordance an exemplary embodiment of the present invention.

TABLE 8

| | processing | flow rate | |
|---|---|---|---|
| | time (sec) | (sccm) | Plasma |
| introducing first reactant | 2 | 1,000 | |
| removing unreacted first reactant | 2 | 1,000 | |
| introducing second reactant | 1 | 1,000 | |
| removing impurities using plasma | 1 | 1,000 | on |
| introducing additional second reactant | 1 | 1,000 | |
| removing unreacted additional second | 1.5 | 1,000 | |
| reactant | | | |

As illustrated in Table 8, although the flow rate of the additional second reactant is substantially identical to that of the second reactant, the processing time of introducing the second reactant is longer than that of the additional second reactant.

### EXAMPLES 1 to 4

Silicon nitride (SiN) layers were formed on substrates using processes substantially identical to those described with reference to FIGS. 8 to 11, respectively. In the processes forming the silicon nitride layers according to the Examples 1 to 4, DCS gases and NH₃ gases were provided for about 20 seconds and about 35 seconds, respectively.

### EXAMPLE 5

A hafnium oxide (HfO₂) layer was formed on a substrate using processes substantially identical to that described with reference to FIG. 12. To form the hafnium oxide layer, TEMAH was used as a first reactant and ozone (O₃) was used as a second reactant. Additionally, an argon plasma was used as a purge gas and as a plasma for removing impurities was applied to remove impurities from the hafnium oxide layer. A deposition ratio was about 0.7 Å/cycle, and the hafnium oxide layer had a thickness of about 40 Å.

### COMPARATIVE EXAMPLE 1

A silicon nitride layer was formed on a substrate by a conventional method. In particular, the silicon nitride layer was formed using an ALD process at a temperature of about 550° C. A DCS gas and an NH₃ gas were provided for about 20 seconds and about 35 seconds, respectively.

### COMPARATIVE EXAMPLE 2

A hafnium oxide layer was formed on a substrate by processes substantially identical to that described with reference to FIG. 12 except a step for removing impurities from the layer using the plasma for removing the impurities. In particular, after introducing a second reactant, an argon gas instead of an argon plasma is introduced in a chamber for 2 seconds as a purge gas so as to remove a non-chemisorbed second reactant from the chamber. Here, the hafnium oxide layer had a thickness of about 40 Å.

FIG. 16 illustrates hydrogen concentrations in the silicon nitride layers according to Comparative Example 1 and Examples 1 to 4.

Referring to FIG. 16, the hydrogen concentration of the silicon nitride layer of Comparative Example 1 is about 11.75 atomic percentage (atomic %), whereas the hydrogen concentration of the silicon nitride layer of Example 1, wherein the nitrogen remote plasma treatment is carried out after the DCS gas is introduced, is about 6.95 atomic %. In addition, the hydrogen concentration of the silicon nitride layer of Example 2, wherein the nitrogen remote plasma treatment is performed after the ammonia gas is introduced, is about 9.98 atomic %. Thus, the silicon nitride layers of Examples 1 and 2 have hydrogen concentrations greatly lower than that of the silicon nitride layer of Comparative Example 1.

The silicon nitride layer of Example 3, wherein the first nitrogen remote plasma treatment is carried out after providing the DCS gas and the second nitrogen remote plasma treatment is performed after introducing the ammonia, has a hydrogen concentration of about 8.81 atomic %. Further, the silicon nitride layer of Example 4, wherein the unreacted DCS gas is removed using the first nitrogen remote plasma treatment and the unreacted ammonia gas is removed using the second nitrogen remote plasma treatment, has a hydrogen concentration of about 11.02 atomic %.

As shown in FIG. 16, the hydrogen concentrations of the silicon nitride layers of Examples 1 to 4 are considerably lower than that of the silicon nitride layer of Comparative Example 1.

As for Examples 1 to 4, the silicon nitride layer of Example 1, wherein the nitrogen remote plasma treatment was performed after the DCS gas is provided, had the lowest hydrogen concentration. According to a basic mechanism of the ALD process, the silicon nitride layer is formed by chemically reacting the DCS gas with the ammonia gas. That is, the adsorption layer such as the silicon layer is formed on the substrate by chemisorbing the DCS gas to the substrate, and then the second reactant such as the ammonia gas is introduced into the chamber. Subsequently, the reactants in the adsorption layer are reacted with the ammonia gas to thereby form the silicon nitride layer. Since the ammonia gas is provided after removing hydrogens in the adsorption layer by the nitrogen remote plasma treatment, the N—H bonds in the silicon nitride layer may be considerably reduced.

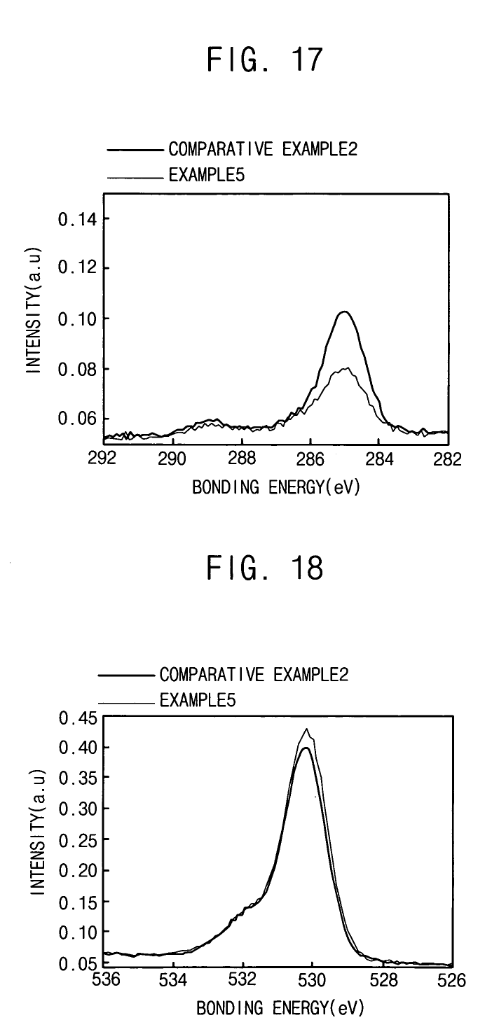

FIG. 17 is a graph showing carbon contents of the HfO₂ layers according to an embodiment of the present invention and consistent with Comparative Example 2 and Example 5 obtained using an X-ray photoemission spectroscopy method. In FIG. 17, as the maximum peak value becomes greater, the carbon content of the HfO₂ layer becomes higher.

Referring to FIG. 17, the HfO₂ layer of Comparative Example 2 has a maximum peak value of about 0.105 au, whereas the HfO₂ layer of Example 5 has a maximum peak value of about 0.082 au. That is, the carbon concentration in the HfO₂ layer of Example 5 is considerably lower than that in the HfO₂ layer of Comparative Example 2.

In accordance with the present invention, carbons are included in the organic precursor as the first reactant. These carbons should be removed from the first reactant through the reaction between the first reactant and the second reactant, and then completely purged from the chamber through the subsequent purging step. However, in practice, some carbons may remain in the chamber, and the remaining carbons may be efficienty removed using the plasma for removing impurities. Accordingly, since the HfO₂ layer of the Example 5 is considerably lower than that of the HfO₂ layer of the Comparative Example 2, the content of impurities such as carbons may be reduced through applying the plasma for removing impurities to the HfO₂ layer.

FIG. 18 is a graph showing oxygen contents of the HfO₂ layers according to an embodiment of the present invention and consistent with Comparative Example 2 and Example 5 obtained using an X-ray photoemission spectroscopy method. In FIG. 18, as the maximum peak value becomes greater, the oxygen content of the HfO₂ layer becomes higher.

Referring to FIG. 18, the HfO₂ layer of Comparative Example 2 has a maximum peak value of about 0.39 au, whereas the HfO₂ layer of the Example 5 has a maximum peak value of about 0.43 au. That is, the oxygen content of the HfO₂ layer of Example 5 is considerably higher than that of the HfO₂ layer of Comparative Example 2. Here, an increase of the oxygen content in the layer means a decrease of the impurities in the layer. Thus, since the HfO₂ layer of Example 5 is considerably higher than that of the HfO₂ layer of Comparative Example 2, the HfO₂ layer with lower impurities may be formed through applying the plasma for removing impurities to the HfO₂ layer.

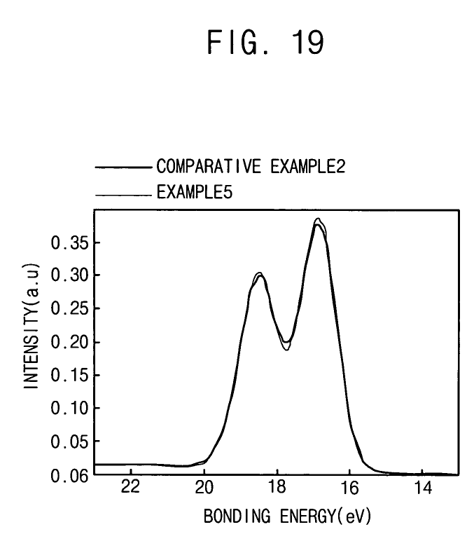

FIG. 19 is a graph showing hafnium contents of the HfO₂ layers according to an embodiment of the present invention and consistent with Comparative Example 2 and Example 5 obtained using an X-ray photoemission spectroscopy method. In FIG. 19, as a full-width half maximum becomes smaller, the content of hafnium coupling only to oxygens becomes higher.

Referring to FIG. 19, the HfO₂ layer of Comparative Example 2 has a greater full-width half maximum than that of the HfO₂ layer of Example 5. That is, the hafnium content of the HfO₂ layer of Example 5 is considerably higher than that of the HfO₂ layer of Comparative Example 2. Here, an increase of hafniums coupling only to oxygens in the layer means a decrease of the impurities in the layer. Thus, since the HfO₂ layer of Comparative Example 2 has a greater full-width half maximum than that of the HfO₂ layer of Example 5, the HfO₂ layer with lower impurities may be formed by applying the plasma for removing the impurities to the HfO₂ layer.

According to an embodiment of the present invention, at least one nitrogen remote plasma treatment is carried out after introducing a first reactant and/or a second reactant. Therefore, the hydrogen bonds in an adsorption layer formed by chemisorbing the first reactant to the substrate, or the hydrogen bond in the layer formed by chemically reacting the first reactant with the second reactant, may be effectively removed. Therefore, a layer having low hydrogen content may be obtained.

In addition, the plasma for removing impurities is applied to the layer formed by an ALD process. Therefore, the impurities in the layer may be efficiently removed from the layer so that the layer may have a greatly reduced leakage current and a superior insulation property.

Furthermore, when the layer may be employed for a dielectric layer of a capacitor, the capacitor may have improved electrical characteristics and enhanced reliability.

Although exemplary embodiments of the present invention have been described, it is understood that the present invention should not be limited to these exemplary embodiments but various changes and modifications can be made by one skilled in the art within the spirit and scope of the present invention as hereinafter claimed.

What is claimed is:

1. A method of forming a layer comprising:
forming a preliminary layer on a substrate by an atomic layer deposition (ALD) process; and
removing impurities from the preliminary layer using a plasma for removing impurities, the plasma being formed from a gas.

2. The method of claim 1, wherein the plasma is generated adjacent to the substrate.

3. The method of claim 1, wherein the plasma is generated apart from the substrate.

4. The method of claim 1, wherein the gas comprises an inert gas, an inactive gas or a mixture thereof.

5. The method of claim 4, wherein the inert gas comprises at least one gas selected from the group consisting of a helium (He) gas, a xenon (Xe) gas, a krypton (Kr) gas and an argon (Ar) gas.

6. The method of claim 4, wherein the inactive gas comprises at least one gas selected from the group consisting of an oxygen (O₂) gas, a hydrogen (H₂) gas, an ammonia (NH₃) gas, a nitrous oxide (N₂O) gas and a nitrogen dioxide (NO₂) gas.

7. The method of claim 1, wherein the preliminary layer comprises oxide, nitride or oxynitride.

8. A method of forming a layer comprising:
loading a substrate into a chamber;
introducing a first reactant into the chamber;
chemisorbing the first reactant to the substrate;
introducing a second reactant into the chamber;
forming a preliminary layer on the substrate by chemically reacting the second reactant with the chemisorbed first reactant; and
forming a layer on the substrate by removing impurities from the preliminary layer using a plasma for removing impurities.

9. The method of claim 8, wherein the first reactant comprises an organic precursor.

10. The method of claim 9, wherein the organic precursor comprises at least one compound selected from the group consisting of an alkoxide compound, an amide compound, and a cyclopentadienyl compound.

11. The method of claim 8, wherein the second reactant comprises an oxygen-containing compound or a nitrogen-containing compound.

12. The method of claim 8, further comprising introducing a purge gas into the chamber to remove a non-chemisorbed first reactant from the chamber before introducing the second reactant.

13. The method of claim 12, wherein the purge gas comprises a plasma phase.

14. The method of claim 8, wherein the second reactant comprises a plasma phase.

15. The method of claim 8, wherein the plasma for removing impurities removes a non-chemisorbed second reactant from the chamber while removing the impurities from the preliminary layer.

16. The method of claim 8, wherein introducing the first reactant, chemisorbing the first reactant, introducing the second reactant, forming the preliminary layer, and forming the layer are repeatedly performed at least once.

17. The method of claim 8, further comprising:
introducing an additional second reactant into the chamber after removing the impurities from the preliminary layer; and
removing a non-chemisorbed additional second reactant from the chamber.

18. The method of claim 17, wherein introducing the first reactant, chemisorbing the first reactant, introducing the second reactant, forming the preliminary layer, forming the layer, introducing the additional second reactant, and removing the non-chemisorbed additional second reactant are repeatedly performed at least once.

19. A method of forming a capacitor of a semiconductor device comprising:
loading a substrate including a lower electrode into a chamber;
providing a first reactant onto the substrate to form an absorption layer on the lower electrode;
removing unreacted first reactant from the chamber;
providing a second reactant onto the adsorption layer to form a dielectric layer on the lower electrode;
removing impurities from the dielectric layer using a plasma for removing impurities; and
forming an upper electrode on the dielectric layer.

20. The method of claim 19, wherein the lower and the upper electrodes comprise at least one compound selected from silicon compound, metal, metal oxide, metal nitride and metal oxynitride.
